(19) United States
(12) Patent Application Publication
(10) Pub. No.: US 2025/0014996 A1
(43) Pub. Date: Jan. 9, 2025

(54) SEMICONDUCTOR STORAGE DEVICE AND MANUFACTURING METHOD OF SEMICONDUCTOR STORAGE DEVICE

(71) Applicant: Kioxia Corporation, Tokyo (JP)

(72) Inventor: Kosei NODA, Yokkaichi Mie (JP)

(73) Assignee: Kioxia Corporation, Tokyo (JP)

(21) Appl. No.: 18/760,040

(22) Filed: Jul. 1, 2024

(30) Foreign Application Priority Data
Jul. 6, 2023 (JP) 2023-111719

(51) Int. Cl. H01L 23/528; G11C 16/04; H10B 41/10; H10B 41/27; H10B 41/35; H10B 43/10; H10B 43/27; H10B 43/35

(52) U.S. Cl. CPC H01L 23/5283; G11C 16/0483; H10B 41/10; H10B 41/27; H10B 41/35; H10B 43/10; H10B 43/27; H10B 43/35

(57) ABSTRACT

A semiconductor storage device of an embodiment includes a multi-layered body and a plurality of contacts. The multi-layered body includes a plurality of gate electrode layers and a plurality of insulating layers. The plurality of gate electrode layers include a first gate electrode layer, a second gate electrode, and a third gate electrode layer. The multi-layered body includes a first protruding part protruding from the first gate electrode layer toward a first contact, and a second protruding part protruding from the third gate electrode layer toward a third contact. The first contact is in contact with the first protruding part. A second contact is in contact with the second gate electrode layer. The third contact is in contact with the second protruding part.

### CROSS-REFERENCE TO RELATED APPLICATION

This application is based upon and claims the benefit of priority from Japanese Patent Application No. 2023-111719 filed on Jul. 6, 2023; the entire contents of which are incorporated herein by reference.

### FIELD

Embodiments of the present invention relate to a semiconductor storage device and a manufacturing method of the semiconductor storage device.

### BACKGROUND ART

A semiconductor storage device including a multi-layered body is known. In the multi-layered body, a plurality of gate electrode layers and a plurality of insulating layers are alternately stacked one by one, and a plurality of contacts are provided therein.

### BRIEF DESCRIPTION OF THE DRAWINGS

FIG. 1 is a block diagram showing a part of a configuration of a semiconductor storage device of a first embodiment.

FIG. 2 is a diagram showing an equivalent circuit of a part of a memory cell array of the first embodiment.

FIG. 3 is a cross-sectional view showing a part of the semiconductor storage device of the first embodiment.

FIG. 4 is an enlarged cross-sectional view showing the region surrounded by line F4 shown in FIG. 3.

FIG. 5 is a cross-sectional view showing the semiconductor storage device along line F5-F5 shown in FIG. 4.

FIG. 6 is a cross-sectional view showing a staircase region of the semiconductor storage device of the first embodiment.

FIG. 7 is an enlarged cross-sectional view showing a part of the staircase region of the first embodiment.

FIG. 8A is a view for explaining a manufacturing method of the semiconductor storage device of the first embodiment.

FIG. 8B is a view for explaining the manufacturing method of the semiconductor storage device of the first embodiment.

FIG. 9 is a cross-sectional view showing a staircase region of a semiconductor storage device of a modified example of the first embodiment.

FIG. 10 is a cross-sectional view showing a staircase region of a semiconductor storage device of a second embodiment.

FIG. 11A is a view for explaining a manufacturing method of the semiconductor storage device of the second embodiment.

FIG. 11B is a view for explaining the manufacturing method of the semiconductor storage device of the second embodiment.

FIG. 11C is a view for explaining the manufacturing method of the semiconductor storage device of the second embodiment.

FIG. 12 is a perspective cross-sectional view showing a staircase region of a semiconductor storage device of a third embodiment.

FIG. 13 is a cross-sectional view showing a staircase region of a semiconductor storage device of a modified example of the embodiment.

### DETAILED DESCRIPTION

A semiconductor storage device of an embodiment includes a multi-layered body and a plurality of contacts. The multi-layered body includes a plurality of gate electrode layers and a plurality of insulating layers. The plurality of gate electrode layers and the plurality of insulating layers are alternately stacked one by one in a first direction in the multi-layered body. The plurality of contacts each extend in the first direction. The multi-layered body includes a first region, a second region, and a third region. The first region, the second region, and the third region are in a second direction different from the first direction in order of the first region, the second region, and the third region. The plurality of contacts include a first contact in the first region, a second contact in the second region, and a third contact in the third region. The plurality of gate electrode layers include a first gate electrode layer, a second gate electrode layer, and a third gate electrode layer. The second gate electrode layer is on a first side in the first direction with respect to the first gate electrode layer. The third gate electrode layer is on the first side with respect to the second gate electrode layer. The multi-layered body includes a first protruding part and a second protruding part. The first protruding part has electroconductivity. The first protruding part protrudes from the first gate electrode layer toward the first contact. The second protruding part has electroconductivity. The second protruding part protrudes from the third gate electrode layer toward the third contact. The first contact is in contact with the first protruding part. The second contact is in contact with the second gate electrode layer. The third contact is in contact with the second protruding part.

Hereinafter, a semiconductor storage device and a manufacturing method of the semiconductor storage device of an embodiment will be described with reference to the drawings. In the following description, components having the same or similar functions will be denoted by the same reference signs. Also, duplicate description of the components may be omitted. In the following description, when a reference sign is appended with a number or an alphabetical letter at the end for distinction, the number or the alphabetical letter at the end may be omitted when there is no need for distinguishing. In the present application, terms are defined as follows. In the present application, “parallel,” “orthogonal,” or “the same” may include a case of “substantially parallel,” “substantially orthogonal,” or “substantially the same”. In the present application, “connection” is not limited to a case of being mechanically connected, and may also include a case of being electrically connected. That is, “connection” is not limited to a case in which a plurality of elements are directly connected, and may include a case in which a plurality of elements are connected with another element interposed therebetween.

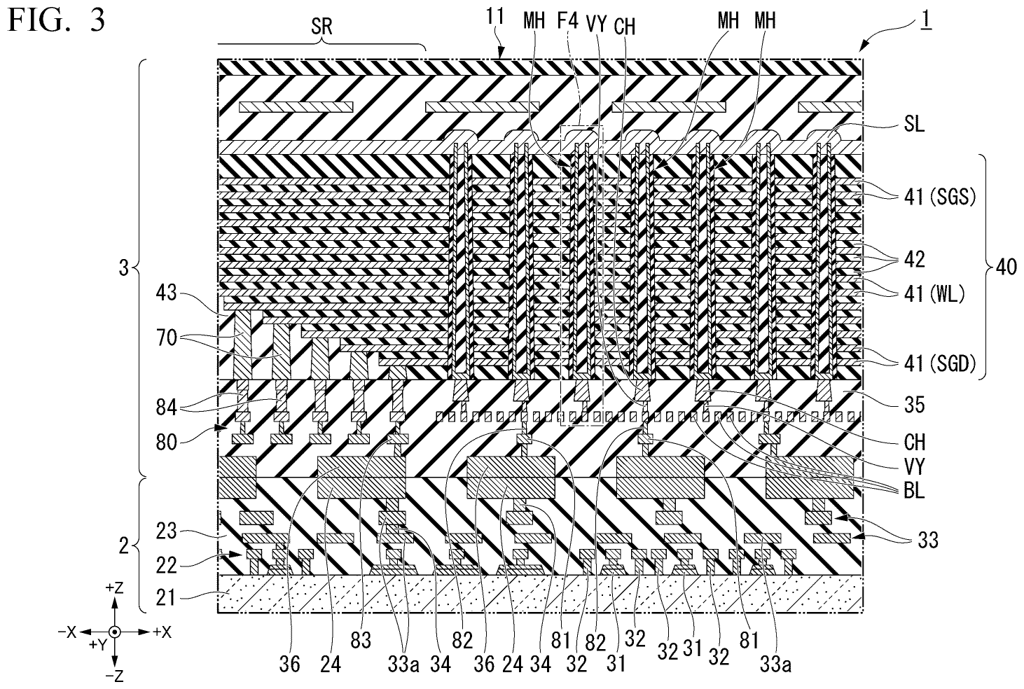

A +X direction, a −X direction, a +Y direction, a −Y direction, a +Z direction, and a −Z direction are defined as follows. The +X direction is a direction in which a word line WL to be described later extends (see FIG. 3). The −X direction is a direction opposite to the +X direction. In a case in which the +X direction and the −X direction do not need to be distinguished from each other, they will be simply referred to as an “X direction”. The +Y direction is a direction that intersects (for example, is orthogonal to) the X direction. The +Y direction is a direction in which a bit line BL extends (see FIG. 3). The −Y direction is a direction opposite to the +Y direction. In a case in which the +Y direction and the −Y direction do not need to be distinguished from each other, they will be simply referred to as a “Y direction”. The +Z direction is a direction that intersects (for example, is orthogonal to) the X direction and the Y direction. The +Z direction is a direction toward a multi-layered body 40 from a bit line BL to be described later (see FIG. 3). The −Z direction is a direction opposite to the +Z direction. In a case in which the +Z direction and the −Z direction do not need to be distinguished from each other, they will be simply referred to as a “Z direction”.

In the following description, a side in the +Z direction may be referred to using “upper” and a side in the −Z direction may be referred to using “lower”. Also, in the following description, a position in the Z direction may be referred to using a “height”. However, these expressions are used for convenience only. These expressions do not define a direction of gravity. The Z direction is an example of a “first direction”. A side in the +Z direction is an example of a “first side”. A side in the −Z direction is an example of a “second side”. The X direction is an example of a “second direction”. In the drawings described below, illustration of components not related to the description may be omitted.

### First Embodiment

### 1. Configuration of Semiconductor Storage Device

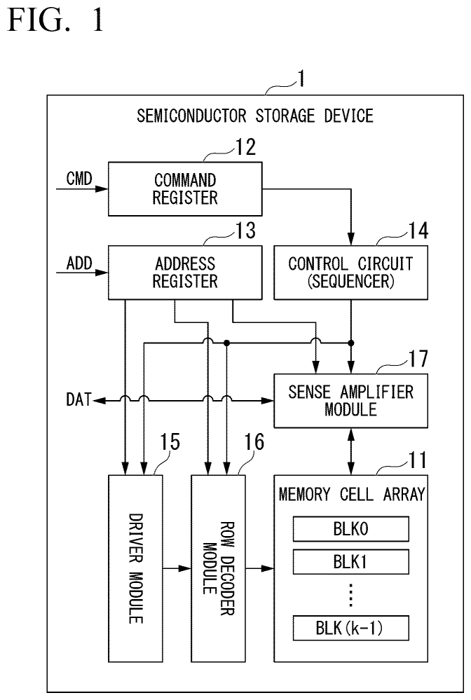

FIG. 1 is a block diagram showing a part of a configuration of a semiconductor storage device 1. The semiconductor storage device 1 is, for example, a nonvolatile semiconductor storage device. The semiconductor storage device 1 is a NAND flash memory. The semiconductor storage device 1 can be connected to an external host device. The semiconductor storage device 1 is used as a storage space for the host device. The semiconductor storage device 1 includes, for example, a memory cell array 11, a command register 12, an address register 13, a control circuit (sequencer) 14, a driver module 15, a row decoder module 16, and a sense amplifier module 17.

The memory cell array 11 includes a plurality of blocks BLK0 to BLK (k−1) (k is an integer of 1 or more). The block BLK is a set of memory cell transistors. The block BLK is used as a data erase unit. A plurality of bit lines and a plurality of word lines are provided in the memory cell array 11. Each of the memory cell transistors is associated with one bit line and one word line.

The command register 12 holds a command CMD received by the semiconductor storage device 1 from the host device. The address register 13 holds address information ADD received by the semiconductor storage device 1 from the host device. The address information ADD is used to select a block BLK, a word line, and a bit line. The control circuit 14 controls various operations of the semiconductor storage device 1. For example, the control circuit 14 executes a write operation, a read operation, an erase operation, or the like of data based on the command CMD held in the command register 12.

The driver module 15 includes a voltage generation circuit and generates voltages used in various operations of the semiconductor storage device 1. The row decoder module 16 transfers a voltage applied to a signal line corresponding to a selected word line to the selected word line. The sense amplifier module 17 applies a desired voltage to each bit line in the write operation. In the read operation, the sense amplifier module 17 determines a data value stored in each memory cell transistor based on a voltage of each bit line, and transfers the determination result to the host device as read data DAT.

### 2. Electrical Configuration of Memory Cell Array

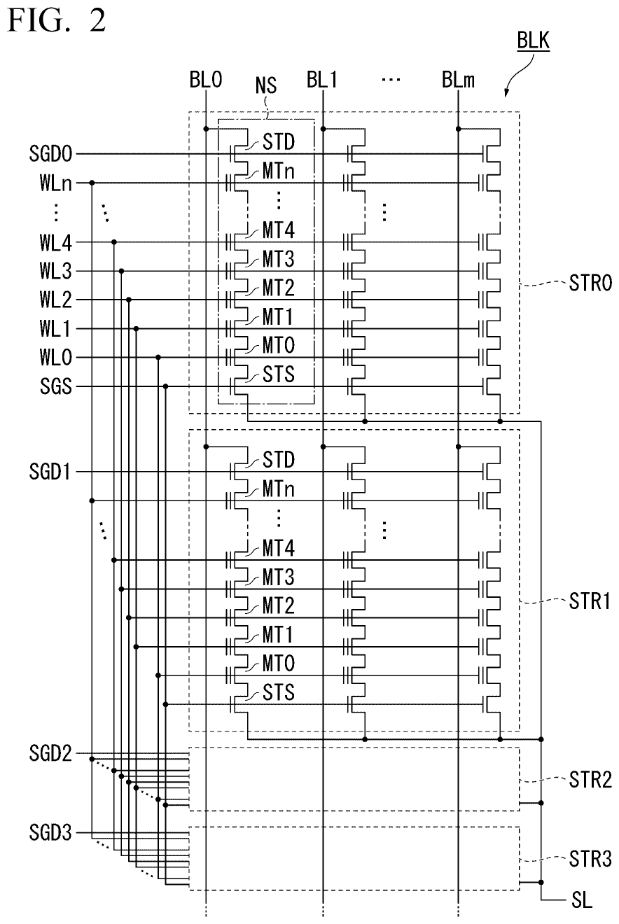

FIG. 2 is a diagram showing an equivalent circuit of a part of the memory cell array 11. FIG. 2 shows one block BLK included in the memory cell array 11. The block BLK includes a plurality of (for example, four) strings STR0 to STR3. Each string STR includes a plurality of NAND strings NS that are respectively associated with bit lines BL0 to BLm (m is an integer of 1 or more). Each NAND string NS includes, for example, a plurality of memory cell transistors MT0 to MTn (n is an integer of 1 or more), one or more drain-side selection transistors STD, and one or more source-side selection transistors STS.

In each NAND string NS, the memory cell transistors MT0 to MTn are connected in series. Each of the memory cell transistors MT includes a control gate and a charge storage. The control gate of the memory cell transistor MT is connected to any one of word lines WL0 to WLn. In each memory cell transistor MT, electric charge is stored in the charge storage according to a voltage applied to the control gate via the word line WL. Each memory cell transistor MT holds a data value non-volatilely.

A drain of the drain-side selection transistor STD is connected to the bit line BL corresponding to the NAND string NS. A source of the drain-side selection transistor STD is connected to one end of the memory cell transistors MT0 to MTn connected in series. A control gate of the drain-side selection transistor STD is connected to any one of the drain-side selection gate lines SGD0 to SGD3. The drain-side selection transistor STD is electrically connected to the row decoder module 16 via the drain-side selection gate line SGD. The drain-side selection transistor STD connects the NAND string NS and the bit line BL when a predetermined voltage is applied to the corresponding drain-side selection gate line SGD.

A drain of the source-side selection transistor STS is connected to the other end of the memory cell transistors MT0 to MTn connected in series. A source of the source-side selection transistor STS is connected to a source line SL. A control gate of the source-side selection transistor STS is connected to a source-side selection gate line SGS. The source-side selection transistor STS connects the NAND string NS and the source line SL when a predetermined voltage is applied to the source-side selection gate line SGS.

In the same block BLK, the control gates of the memory cell transistors MT0 to MTn are commonly connected to the corresponding word lines WL0 to WLn, respectively. In the same string STR, the control gates of the drain-side selection transistors STD are commonly connected to the corresponding drain-side selection gate lines SGD0 to SGD3. The control gates of the source-side selection transistors STS are commonly connected to the source-side selection gate line SGS. In the memory cell array 11, the bit line BL is shared by the NAND strings NS. The same column address is assigned to the NAND strings NS in the plurality of strings STR.

### 3. Physical Configuration of Semiconductor Storage Device

Next, a physical configuration of the semiconductor storage device 1 will be described.

FIG. 3 is a cross-sectional view showing a part of the semiconductor storage device 1. The semiconductor storage device 1 includes, for example, a first chip 2 and a second chip 3.

### <3.1 First Chip>

The first chip 2 is a circuit chip including peripheral circuits. The first chip 2 includes, for example, a semiconductor substrate 21, a peripheral circuit 22, an insulating part 23, and a plurality of pads 24.

The semiconductor substrate 21 is a substrate serving as a base part of the first chip 2. At least a part of the semiconductor substrate 21 has a plate shape extending in the X direction and the Y direction. The semiconductor substrate 21 is formed of a semiconductor material such as, for example, silicon.

The peripheral circuit 22 is a circuit for making the memory cell array 11 described above function. The peripheral circuit 22 includes one or more of the command register 12, the address register 13, the control circuit 14, the driver module 15, the row decoder module 16, and the sense amplifier module 17 described above. The peripheral circuit 22 includes, for example, a plurality of transistors 31, a plurality of contacts 32, a plurality of wiring layers 33, and a plurality of vias 34.

The transistor 31 is provided on the semiconductor substrate 21. Each of the plurality of the contacts 32 has electroconductivity. Each of the plurality of the contacts 32 has electroconductivity extends in the Z direction. Each of the plurality of the contacts 32 is in contact with a source region, a drain region, or a gate electrode of the transistor 31. The plurality of wiring layers 33 are separately disposed at a plurality of heights. Each of the wiring layers 33 includes a plurality of wirings 33a extending in the X direction or the Y direction. The vias 34 are each an electrical connection part extending in the Z direction within the first chip 2. The plurality of vias 34 include, for example, the via 34 connecting two wirings 33a disposed at different heights, and the via 34 connecting the wiring 33a and the pad 24.

The insulating part 23 covers the plurality of transistors 31, the plurality of contacts 32, the plurality of wiring layers 33, and the plurality of vias 34. The plurality of pads 24 are provided on a surface of the insulating part 23. Each of the pads 24 is electrically connected to the wiring 33a via the via 34.

### <3.2 Second Chip>

The second chip 3 is an array chip that includes the memory cell array 11. The second chip 3 includes, for example, the memory cell array 11, an insulating part 35, and a plurality of pads 36. Here, the insulating part 35 and the plurality of pads 36 will be described, and the memory cell array 11 will be described later.

The insulating part 35 covers the memory cell array 11. The plurality of pads 36 are provided on a surface of the insulating part 35. Each of the pads 36 is electrically connected to a wiring (for example, a wiring 81 or a wiring 83) included in a wiring part 80 of the memory cell array 11 to be described later. In the present embodiment, the plurality of pads 24 of the first chip 2 and the plurality of pads 36 of the second chip 3 are adhered together facing each other. Therefore, the first chip 2 and the second chip 3 are integrated.

### 4. Physical Configuration of Memory Cell Array

Next, a physical configuration of the memory cell array 11 will be described.

As shown in FIG. 3, the memory cell array 11 includes a multi-layered body 40, a source line SL, a plurality of memory pillars MH, a plurality of bit lines BL, a plurality of contacts CH for memory pillars, a plurality of contacts VY for memory pillars, a plurality of contacts 70 for conductive layers, and the wiring part 80.

### <4.1 Multi-Layered Body>

First, the multi-layered body 40 will be described.

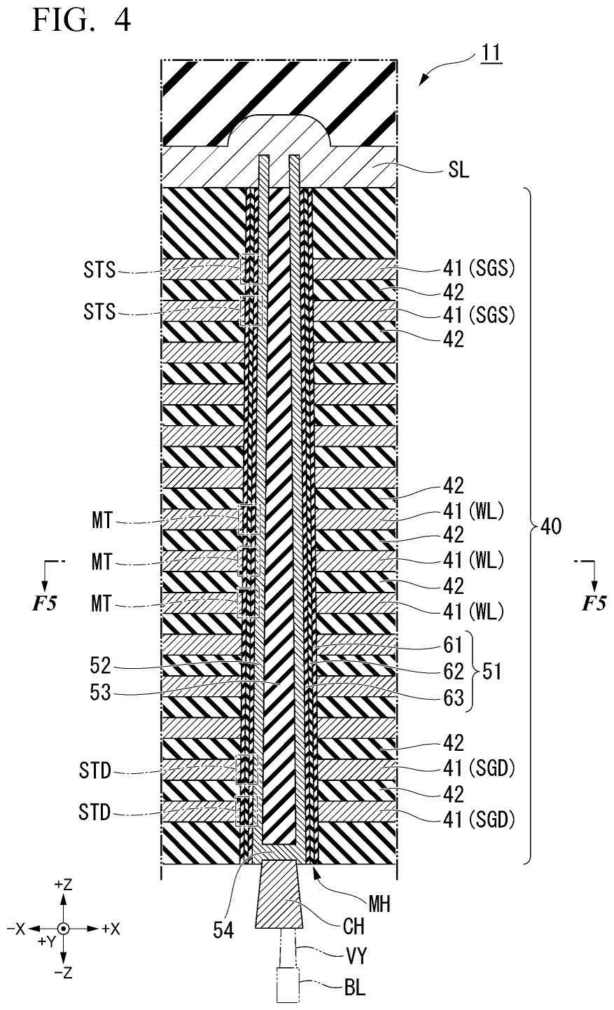

FIG. 4 is an enlarged cross-sectional view showing the region surrounded by line F4 of the semiconductor storage device 1 shown in FIG. 3. The multi-layered body 40 includes a plurality of conductive layers 41, a plurality of insulating layers 42, and an insulating part 43. The plurality of conductive layers 41 and the plurality of insulating layers 42 are alternately stacked one by one in the Z direction.

The conductive layers 41 each extend in the X direction and the Y direction. Each of the conductive layers 41 contains a conductive material (first material) such as, for example, tungsten, molybdenum, or silicon doped with impurities. The conductive layer 41 is an example of a “gate electrode layer”.

One or more (for example, a plurality of) conductive layers 41 positioned on a lower side among the plurality of conductive layers 41 function as the drain-side selection gate line SGD. The drain-side selection gate line SGD is commonly provided for the plurality of memory pillars MH aligned in the X direction or the Y direction. The drain-side selection gate line SGD and a channel layer 52 (to be described later) of each of the memory pillars MH intersect at an intersecting portion. The intersecting portion functions as the drain-side selection transistor STD described above.

One or more (for example, a plurality of) conductive layers 41 positioned on an upper side among the plurality of conductive layers 41 function as the source-side selection gate line SGS. The source-side selection gate line SGS is commonly provided for the plurality of memory pillars MH aligned in the X direction or the Y direction. The source-side selection gate line SGS and the channel layer 52 of each memory pillar MH intersect at an intersecting portion. The intersecting portion functions as the source-side selection transistor STS described above.

Of the plurality of conductive layers 41, at least a part of the remaining conductive layers 41 each provided between the conductive layers 41 functioning as the drain-side selection gate line SGD and the source-side selection gate line SGS functions as the word line WL. The word line WL is commonly provided for the plurality of memory pillars MH aligned in the X direction and the Y direction. In the present embodiment, the word line WL and the channel layer 52 of each memory pillar MH intersect at an intersecting portion. The intersecting portion functions as the memory cell transistor MT. The memory cell transistor MT will be described in detail later.

In the present embodiment, the plurality of conductive layers 41 have lengths in the X direction different from each other. For example, the plurality of conductive layers 41 extend further in the −X direction as the conductive layer 41 becomes positioned farther on the +Z direction side. Therefore, the multi-layered body 40 has a staircase region SR having end portions of the plurality of conductive layers 41 disposed in a staircase shape. The staircase region SR is an example of a connection region in which the plurality of contacts 70 and the plurality of conductive layers 41 are connected.

The insulating layer 42 is provided between two conductive layers 41 adjacent to each other in the Z direction. The insulating layer 42 is an interlayer insulating film that insulates the two conductive layers 41. The insulating layer 42 extends in the X direction and the Y direction. The insulating layer 42 is formed of, for example, a film containing silicon and oxygen.

The insulating part 43 is provided in the staircase region SR. The insulating part 43 is an insulating part that covers end portions of the plurality of conductive layers 41 disposed in a staircase shape. The insulating part 43 is formed using, for example, tetraethyl orthosilicate (TEOS, Si(OC₂H₅)₄).

### <4.2 Source Line>

The source line SL is disposed above the multi-layered body 40. The source line SL is a conductive layer extending in the X direction and the Y direction. The source line SL contains a conductive material such as tungsten, molybdenum, or silicon doped with impurities.

### <4.3 Memory Pillar>

The plurality of memory pillars MH are aligned in the X direction and the Y direction (see FIG. 3). Each of the memory pillars MH extends in the Z direction within the multi-layered body 40. Each memory pillar MH penetrates the multi-layered body 40. An upper end of the memory pillar MH is in contact with the source line SL. On the other hand, a lower end of each memory pillar MH is in contact with the contact CH to be described later.

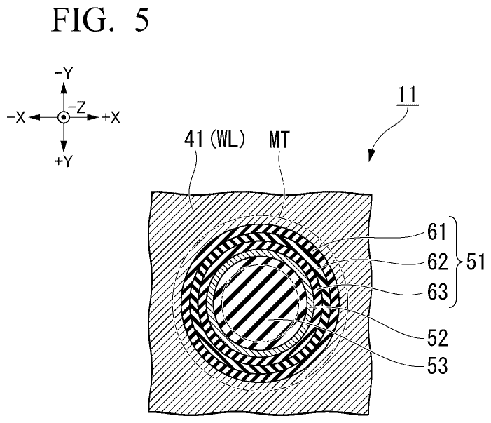

FIG. 5 is a cross-sectional view showing the semiconductor storage device 1 along line F5-F5 shown in FIG. 4. The memory pillar MH includes, for example, a memory film (multilayer film) 51, a channel layer 52, an insulating core 53, and a cap part 54 (see FIG. 4).

The memory film 51 is provided on the outer circumferential side of the channel layer 52. The memory film 51 is positioned between the plurality of conductive layers 41 and the channel layer 52. The memory film 51 includes, for example, a block insulating film 61, a charge trap film 62, and a tunnel insulating film 63.

The block insulating film 61 is provided between the plurality of conductive layers 41 and the charge trap film 62. The block insulating film 61 is an insulating film that suppresses back tunneling. Back tunneling is a phenomenon in which electric charge returns from the word line WL to the charge trap film 62. The block insulating film 61 is formed in an annular shape. The block insulating film 61 extends in the Z direction. The block insulating film 61 is provided, for example, over the entire length of the memory pillar MH in the Z direction. The block insulating film 61 is a multi-layered structure film. In the multi-layered structure film, a plurality of insulating films such as, for example, a film containing silicon and oxygen or a film containing a metal and oxygen are stacked. An example of the film containing a metal and oxygen is aluminum oxide. The block insulating film 61 may contain a high dielectric constant material (high-k material) such as silicon nitride or hafnium oxide.

The charge trap film 62 is positioned between the block insulating film 61 and the tunnel insulating film 63. The charge trap film 62 is formed in an annular shape. The charge trap film 62 extends in the Z direction. The charge trap film 62 is provided, for example, over the entire length of the memory pillar MH in the Z direction. The charge trap film 62 has a large number of crystal defects (trapping levels). The charge trap film 62 is a functional film capable of trapping charges in the crystal defects. The charge trap film 62 is formed of, for example, a film containing silicon and nitrogen. A part of the charge trap film 62 adjacent to each word line WL is an example of a “charge storage” that can store information by accumulating charges.

The tunnel insulating film 63 is provided between the channel layer 52 and the charge trap film 62. The tunnel insulating film 63 is formed, for example, in an annular shape along an outer circumferential surface of the channel layer 52. The tunnel insulating film 63 extends in the Z direction along the channel layer 52. The tunnel insulating film 63 is provided, for example, over the entire length of the memory pillar MH in the Z direction. The tunnel insulating film 63 is a potential barrier between the channel layer 52 and the charge trap film 62. The tunnel insulating film 63 is formed of a film containing silicon and oxygen or a film containing silicon, oxygen, and nitrogen.

Therefore, a metal-Al-nitride-oxide-silicon (MANOS) type memory cell transistor MT is formed at the same height as each word line WL. The MANOS type memory cell transistor MT is formed of an end portion of the word line WL adjacent to the memory pillar MH, the block insulating film 61, the charge trap film 62, the tunnel insulating film 63, and the channel layer 52. Further, the memory film 51 may have a floating gate type charge storage (floating gate electrode) instead of the charge trap film 62 as the charge storage. The floating gate electrode is formed of, for example, silicon doped with impurities.

The insulating core 53 is provided inside the channel layer 52. The insulating core 53 fills at least a part of the inside of channel layer 52. The insulating core 53 is formed of a film containing silicon and oxygen. A part of the insulating core 53 is formed in an annular shape along an inner circumferential surface of the channel layer 52. The insulating core 53 may have a space (air gap) inside the insulating core 53. The insulating core 53 extends in the Z direction. The insulating core 53 is provided, for example, across most of the memory pillar MH in the Z direction excluding a lower end portion of the memory pillar MH (see FIG. 4).

Next, returning to FIG. 4, the cap part 54 will be described. The cap part 54 is provided on a lower side of the insulating core 53. The cap part 54 is a semiconductor portion formed of a semiconductor material such as amorphous silicon or polysilicon. The cap part 54 may be doped with impurities. The cap part 54 is disposed on an inner circumferential side of a lower end portion of the memory film 51. The cap part 54 is formed integrally with the channel layer 52. The cap part 54, together with a lower end portion of the channel layer 52, forms the lower end portion of the memory pillar MH. The contact CH is in contact with the cap part 54 in the Z direction.

### <4.4 Bit Line>

Next, returning to FIG. 3, the bit line BL will be described.

The bit line BL is a wiring for selecting one memory pillar MH from among the plurality of memory pillars MH. The plurality of bit lines BL are disposed below the multi-layered body 40. The plurality of bit lines BL are aligned in the X direction at intervals in the X direction. Each of the bit lines BL extends in the Y direction. Each bit line BL extends to pass beneath the plurality of corresponding memory pillars MH.

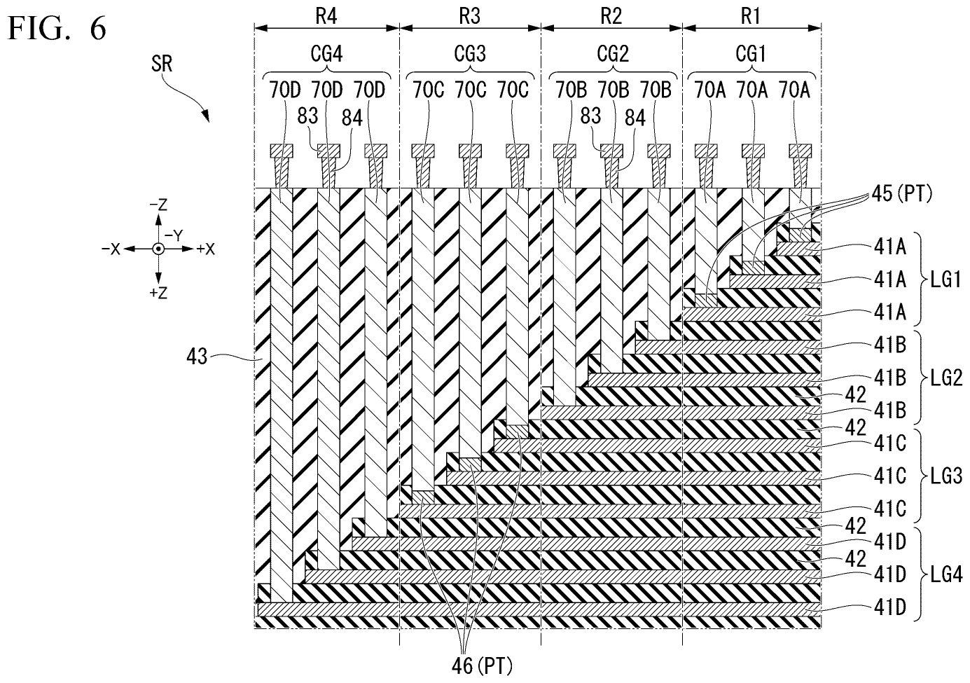

Each bit line BL overlaps the plurality of memory pillars MH when viewed from the Z direction (see FIG. 6). Each bit line BL is connected to the channel layer 52 of the memory pillar MH via the contact VY and the contact CH. Therefore, the memory cell transistor MT can be optionally selected from among the plurality of memory cell transistors MT disposed three-dimensionally by a combination of the word line WL and the bit line BL.

### <4.5 Contact for Conductive Layer>

As shown in FIG. 3, the contact 70 is an electrical connection part that electrically connects the conductive layer 41 and the wiring 83 (to be described later) included in the wiring part 80. The plurality of contacts 70 are disposed, for example, in the staircase region SR of the multi-layered body 40. The plurality of contacts 70 extend in the Z direction. For example, the plurality of contacts 70 have lengths in the Z direction different from each other. Each of the contacts 70 contains a conductive material such as tungsten, molybdenum, or silicon doped with impurities. An upper end of each contact 70 is electrically connected to the corresponding conductive layer 41. A lower end of each contact 70 is electrically connected to the wiring 83 via a via 84 to be described later.

### <4.6 Wiring Part>

Next, the wiring part 80 will be described. The wiring part 80 is disposed, for example, between the multi-layered body 40 and the semiconductor substrate 21. The wiring part 80 includes, for example, a plurality of wirings 81, a plurality of vias 82, a plurality of wirings 83, and a plurality of vias 84.

The wiring 81 is an electrical connection part that electrically connects the bit line BL and the pad 36. The plurality of wirings 81 are disposed, for example, below the plurality of bit lines BL. Each of the wirings 81 extends, for example, in the X direction or the Y direction. The via 82 electrically connecting the wiring 81 and the bit line BL is provided between the wiring 81 and the bit line BL.

The wiring 83 is an electrical connection part that electrically connects the contact 70 for the conductive layer and the pad 36. The wiring 83 is electrically connected to the conductive layer 41 via the via 84 and the contact 70 for the conductive layer. A voltage is applied to the wiring 83 to select the conductive layer 41 (the word line WL, the drain-side selection gate line SGD, or the source-side selection gate line SGS).

### 5. Configuration of Staircase Region

Next, a configuration of the staircase region SR will be described.

FIG. 6 is an enlarged cross-sectional view showing the staircase region SR. Further, from FIG. 6 onward, for convenience of explanation, the −Z direction will be shown as an upper side and the +Z direction will be shown as a lower side.

As shown in FIG. 6, the staircase region SR includes, for example, a first region R1, a second region R2, a third region R3, and a fourth region R4. These regions are aligned in the −X direction in order of the first region R1, the second region R2, the third region R3, and the fourth region R4. The first region R1, the second region R2, the third region R3, and the fourth region R4 are, for example, regions in which the staircase region SR is divided into four in the X direction. However, sizes of the first region R1, the second region R2, the third region R3, and the fourth region R4 may be different from each other.

### (Contacts of First to Fourth Groups)

As shown in FIG. 6, the plurality of contacts 70 extend in the Z direction and have lengths in the Z direction different from each other. For example, the plurality of contacts 70 extend further in the +Z direction as the contact 70 becomes positioned farther on the −X direction side. Each of the contacts 70 is an example of a “pillar-shaped body”.

The plurality of contacts 70 are disposed separately in the first region R1, the second region R2, the third region R3, and the fourth region R4. The plurality of contacts 70 include a plurality of contacts 70A of a first group CG1, a plurality of contacts 70B of a second group CG2, a plurality of contacts 70C of a third group CG3, and a plurality of contacts 70D of a fourth group CG4.

The plurality of contacts 70A of the first group CG1 are the plurality of contacts 70 disposed in the first region R1. The plurality of contacts 70A of the first group CG1 extend further in the +Z direction as the contact 70A becomes positioned farther on the −X direction side in the first region R1. One contact 70A included in the plurality of contacts 70A of the first group CG1 is an example of a “first contact”.

The plurality of contacts 70B of the second group CG2 are the plurality of contacts 70 disposed in the second region R2. The plurality of contacts 70B of the second group CG2 extend further in the +Z direction as the contact 70B becomes positioned farther on the −X direction side in the second region R2. One contact 70B included in the plurality of contacts 70B of the second group CG2 is an example of a “second contact”.

The plurality of contacts 70C of the third group CG3 are the plurality of contacts 70 disposed in the third region R3. The plurality of contacts 70C of the third group CG3 extend further in the +Z direction as the contact 70C becomes positioned farther on the −X direction side in the third region R3. One optionally selected contact 70C included in the plurality of contacts 70C of the third group CG3 is an example of a “third contact”.

The plurality of contacts 70D of the fourth group CG4 are the plurality of contacts 70 disposed in the fourth region R4. The plurality of contacts 70D of the fourth group CG4 extend further in the +Z direction as the contact 70D becomes positioned farther on the −X direction side in the fourth region R4. One optionally selected contact 70D included in the plurality of contacts 70D of the fourth group CG4 is an example of a “fourth contact”.

### (Conductive Layers of First to Fourth Groups)

As shown in FIG. 6, the plurality of conductive layers 41 include a plurality of conductive layers 41A of a first group LG1, a plurality of conductive layers 41B of a second group LG2, a plurality of conductive layers 41C of a third group LG3, and a plurality of conductive layers 41D of a fourth group LG4.

The plurality of conductive layers 41A of the first group LG1 are the plurality of conductive layers 41 corresponding to the plurality of contacts 70A of the first group CG1. In the present application, “corresponding” means that they are electrically connected to each other. The plurality of conductive layers 41A of the first group LG1 extend further in the −X direction as the conductive layer 41 becomes positioned farther on the +Z direction side. One conductive layer 41A (the conductive layer 41A corresponding to the first contact described above) included in the plurality of conductive layers 41A of the first group LG1 is an example of a “first gate electrode layer”.

The plurality of conductive layers 41B of the second group LG2 are the plurality of conductive layers 41 corresponding to the plurality of contacts 70B of the second group CG2. The plurality of conductive layers 41B of the second group LG2 are disposed on the +Z direction side with respect to the plurality of conductive layers 41A of the first group LG1. The plurality of conductive layers 41B of the second group LG2 are disposed between the plurality of conductive layers 41A of the first group LG1 and the plurality of conductive layers 41C of the third group LG3 in the Z direction. One conductive layer 41B (the conductive layer 41B corresponding to the second contact described above) included in the plurality of conductive layers 41B of the second group LG2 is an example of a “second gate electrode layer”.

The plurality of conductive layers 41C of the third group LG3 are the plurality of conductive layers 41 corresponding to the plurality of contacts 70C of the third group CG3. The plurality of conductive layers 41C of the third group LG3 are disposed on the +Z direction side with respect to the plurality of conductive layers 41B of the second group LG2. The plurality of conductive layers 41C of the third group LG3 are disposed between the plurality of conductive layers 41B of the second group LG2 and the plurality of conductive layers 41D of the fourth group LG4 in the Z direction. One conductive layer 41C (the conductive layer 41C corresponding to the third contact described above) included in the plurality of conductive layers 41C of the third group LG3 is an example of a “third gate electrode layer”.

The plurality of conductive layers 41D of the fourth group LG4 are the plurality of conductive layers 41 corresponding to the plurality of contacts 70D of the fourth group CG4. The plurality of conductive layers 41D of the fourth group LG4 are disposed on the +Z direction side with respect to the plurality of conductive layers 41C of the third group LG3. One conductive layer 41D (the conductive layer 41D corresponding to the fourth contact described above) included in the plurality of conductive layers 41D of the fourth group LG4 is an example of a “fourth gate electrode layer”.

### (Conductive Protruding Part)

As shown in FIG. 6, the multi-layered body 40 includes a plurality of first protruding parts 45 and a plurality of second protruding parts 46.

The plurality of first protruding parts 45 are provided in the first region R1. The first protruding parts 45 are each provided on a surface on the −Z direction side of an end portion of the conductive layer 41A of the first group LG1. The first protruding part 45 is a conductive protruding part protruding in the −Z direction from the conductive layer 41A. The first protruding part 45 protrudes from the conductive layer 41A toward the contact 70A included in the first group CG1. The first protruding part 45 is in contact with the contact 70A. In other words, the first protruding part 45 is disposed between the conductive layer 41A and the contact 70A in the Z direction, and electrically connects the conductive layer 41A and the contact 70A.

In the present embodiment, the first protruding part 45 is provided on each of the plurality of conductive layers 41A of the first group LG1. Each contact 70A included in the plurality of contacts 70A of the first group CG1 is in contact with the first protruding part 45 provided on the conductive layer 41A that is included in the plurality of conductive layers 41A of the first group LG1 and corresponds to the contact 70A. In the present embodiment, a width in the X direction of an end of the first protruding part 45 in the −Z direction is the same as a width in the X direction of an end in the +Z direction of the contact 70A connected to the first protruding part 45.

The plurality of second protruding parts 46 are provided in the third region R3. The second protruding parts 46 are each provided on a surface on the −Z direction side of an end portion of the conductive layer 41C of the third group LG3. The second protruding part 46 is a conductive protruding part protruding in the −Z direction from the conductive layer 41C. The second protruding part 46 protrudes from the conductive layer 41C toward the contact 70C of the third group CG3. The second protruding part 46 is in contact with the contact 70C. In other words, the second protruding part 46 is disposed between the conductive layer 41C and the contact 70C in the Z direction. The second protruding part 46 electrically connects the conductive layer 41C and the contact 70C.

In the present embodiment, the second protruding part 46 is provided on each of the plurality of conductive layers 41C of the third group LG3. Each contact 70C included in the plurality of contacts 70C of the third group CG3 is in contact with the second protruding part 46 provided on the conductive layer 41C that is included in the plurality of conductive layers 41C of the third group LG3 and corresponds to the contact 70C. In the present embodiment, a width in the X direction of an end of the second protruding part 46 in the −Z direction is the same as a width in the X direction of an end in the +Z direction of the contact 70C connected to the second protruding part 46.

The first protruding part 45 and the second protruding part 46 are redeposition parts formed by, for example, re-depositing a material contained in the conductive layer 41. The first protruding part 45 and the second protruding part 46 are formed to protrude from the surface of the conductive layer 41 by selectively re-depositing the material contained in the conductive layer 41 using, for example, a chemical vapor deposition (CVD). The material (first material) contained in the conductive layer 41 and re-deposited is, for example, tungsten, molybdenum, silicon doped with impurities, or the like. The material contained in the conductive layer 41 and re-deposited is not limited. Further, the first protruding part 45 and the second protruding part 46 may be protruding parts formed by redeposition using a method other than CVD, and may be protruding parts formed using a method other than redeposition. In the following description, in a case in which the first protruding part 45 and the second protruding part 46 do not need to be distinguished from each other, they will be referred to using a “protruding part PT”.

On the other hand, the second region R2 and the fourth region R4 of the multi-layered body 40 are not provided with the protruding part corresponding to the protruding part PT. Therefore, each contact 70B included in the plurality of contacts 70B of the second group CG2 is in contact with the conductive layer 41B included in the plurality of conductive layers 41B of the second group LG2 and corresponding to the contact 70B without the above-described protruding part interposed. Also, each contact 70D included in the plurality of contacts 70D of the fourth group CG4 is in contact with the conductive layer 41D included in the plurality of conductive layers 41D of the fourth group LG4 and corresponding to the contact 70D without the above-described protruding part interposed.

When the above is described in other words, in the multi-layered body 40, a region in which the plurality of protruding parts PT (for example, the plurality of first protruding parts 45 or the plurality of second protruding parts 46) are provided (for example, the first region R1 or the third region R3) and a region in which the protruding parts PT are not present (for example, the second region R2 and the fourth region R4) are disposed to be aligned alternately in the X direction.

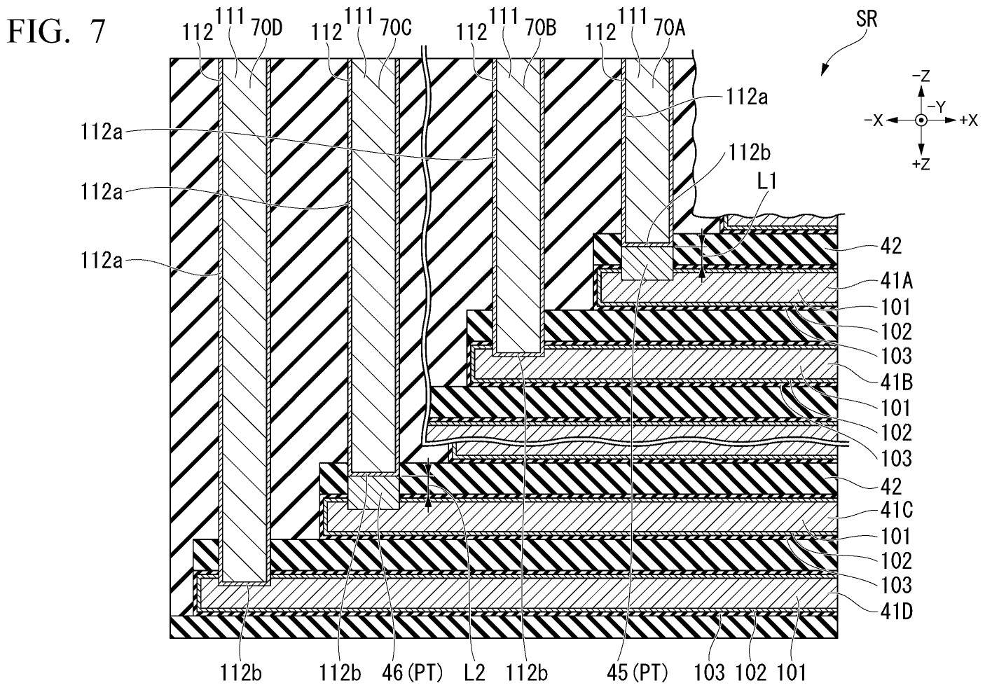

FIG. 7 is an enlarged cross-sectional view showing a part of the staircase region SR of the present embodiment. First, an example of a configuration of the conductive layer 41 will be described. The conductive layer 41 includes, for example, a conductive portion 101, a barrier metal film 102, and an insulating film 103.

The conductive portion 101 is a portion in which a main part of the conductive layer 41 is formed. The conductive portion 101 extends in a layer shape in the X direction and the Y direction. The conductive portion 101 contains the conductive material described above (for example, tungsten, molybdenum, or silicon doped with impurities).

The barrier metal film 102 is a film for suppressing diffusion of the conductive material contained in the conductive portion 101. The barrier metal film 102 is provided along a surface of the conductive portion 101. For example, the barrier metal film 102 is provided along both surfaces of the conductive portion 101 on the +Z direction side and the −Z direction side. The barrier metal film 102 is formed of, for example, a material containing titanium, a material containing titanium and nitrogen, a material containing tantalum, a material containing tantalum and nitrogen, a material containing tungsten and nitrogen, or the like.

The insulating film 103 is an insulating film provided on a surface of the conductive layer 41. The insulating film 103 forms a part of the block insulating film 61, for example, at a portion in which the memory pillar MH and the conductive layer 41 intersect. The insulating film 103 is positioned on a side opposite to the conductive portion 101 with respect to the barrier metal film 102. The insulating film 103 is provided along a surface of the barrier metal film 102. For example, the insulating film 103 is provided along both surfaces of the barrier metal film 102 on the +Z direction side and the −Z direction side. The insulating film 103 is, for example, aluminum oxide. A material of the insulating film 103 is not limited. Also, the insulating film 103 may be omitted.

Next, an example of a configuration of the contact 70 will be described. The contact includes, for example, a conductive portion 111 and a barrier metal film 112.

The conductive portion 111 is a portion that forms a main part of the contact 70. The conductive portion 111 extends in a columnar shape in the Z direction. The conductive portion 111 contains the conductive material described above (for example, tungsten, molybdenum, or silicon doped with impurities).

The barrier metal film 112 is a film for suppressing diffusion of the conductive material contained in the conductive portion 111. The barrier metal film 112 is provided along a surface of the conductive portion 111. For example, the barrier metal film 112 has a circumferential surface portion 112a extending in the Z direction along a circumferential surface of the conductive portion 111, and a bottom surface portion 112b provided along a bottom surface of the conductive portion 111 on the +Z direction side. The barrier metal film 112 forms, for example, a surface of the contact 70. The barrier metal film 112 is formed of, for example, a material containing titanium, a material containing titanium and nitrogen, a material containing tantalum, a material containing tantalum and nitrogen, a material containing tungsten and nitrogen, or the like.

As shown in FIG. 7, the first protruding part 45 is provided between the conductive layer 41A and the contact 70A in the Z direction. Therefore, in a region (first region R1) in which the first protruding part 45 is present, the barrier metal film 112 of the contact 70A and the conductive layer 41A (for example, the barrier metal film 102 of the conductive layer 41A) are separated from each other. There is a distance L1 between the barrier metal film 112 of the contact 70A and the conductive layer 41A. In the present embodiment, a part of the first protruding part 45 penetrates the insulating film 103 and the barrier metal film 102 of the conductive layer 41A to be positioned inside the conductive layer 41A.

On the other hand, in a region (second region R2) in which the first protruding part 45 is not present, the contact 70B is in contact with the conductive layer 41B. For example, a part of the contact 70B penetrates the insulating film 103 and the barrier metal film 102 of the conductive layer 41B to be positioned inside the conductive layer 41B. In this case, in the region (second region R2) in which the first protruding part 45 is not present, the barrier metal film 112 of the contact 70B and the conductive layer 41B (for example, the barrier metal film 102 of the conductive layer 41B) are in contact with each other.

Similarly, the second protruding part 46 is provided between the conductive layer 41C and the contact 70C in the Z direction. Therefore, in a region (the third region R3) in which the second protruding part 46 is present, the barrier metal film 112 of the contact 70C and the conductive layer 41C (for example, the barrier metal film 102 of the conductive layer 41C) are separated from each other. There is a distance L2 between the barrier metal film 112 of the contact 70C and the conductive layer 41C. In the present embodiment, a part of the second protruding part 46 penetrates the insulating film 103 and the barrier metal film 102 of the conductive layer 41C to be positioned inside the conductive layer 41C.

On the other hand, in a region (the fourth region R4) in which the second protruding part 46 is not present, the contact 70D is in contact with the conductive layer 41D. For example, a part of the contact 70D penetrates the insulating film 103 and the barrier metal film 102 of the conductive layer 41D to be positioned inside the conductive layer 41D. In this case, in the region (the fourth region R4) in which the second protruding part 46 is not present, the barrier metal film 112 of the contact 70D and the conductive layer 41D (for example, the barrier metal film 102 of the conductive layer 41D) are in contact with each other.

As described above, in the present embodiment, in a cross section (the cross section shown in FIG. 7) in the X direction and the Y direction, a shortest distance (for example, a zero distance) between the barrier metal film 112 of the contact 70B and the conductive layer 41B is smaller than a shortest distance L1 between the barrier metal film 112 of the contact 70A and the conductive layer 41A, and is smaller than a shortest distance L3 between the barrier metal film 112 of the contact 70C and the conductive layer 41C. Similarly, in the cross section in the X direction and the Y direction, a shortest distance (for example, a zero distance) between the barrier metal film 112 of the contact 70D and the conductive layer 41D is smaller than the shortest distance L1 between the barrier metal film 112 of the contact 70A and the conductive layer 41A, and is smaller than the shortest distance L2 between the barrier metal film 112 of the contact 70C and the conductive layer 41C. In other words, for example, if there is a distance between the barrier metal film 112 (for example, the bottom surface portion 112b of the barrier metal film 112) of the contact 70 and the conductive layer 41, it can be said that there is the protruding part PT between the contact 70 and the conductive layer 41.

Further, in the present embodiment, an example in which the contact 70 includes the barrier metal film 112 has been described. However, the contact 70 may not include the barrier metal film 112. Even in this case, in a case in which a form of crystal grains (a size of crystal grains, a packing density of crystal grains, or the like) is different between the contact 70 and the protruding part PT, impurities (such as oxygen) are present at an interface between the contact 70 and the protruding part PT, internal impurities are different between the contact 70 and the protruding part PT, or the like, it can be said that there is the protruding part PT between the contact 70 and the conductive layer 41. Also, from another point of view, in a case in which a form of crystal grains (a size of crystal grains, a packing density of crystal grains, or the like) is different between the conductive layer 41 and the protruding part PT, impurities (such as oxygen) are present at an interface between the conductive layer 41 and the protruding part PT, internal impurities are different between the conductive layer 41 and the protruding part PT, or the like, it can be said that there is the protruding part PT between the contact 70 and the conductive layer 41.

### 6. Manufacturing Method of Semiconductor Storage Device

Next, a manufacturing method of the semiconductor storage device 1 will be described.

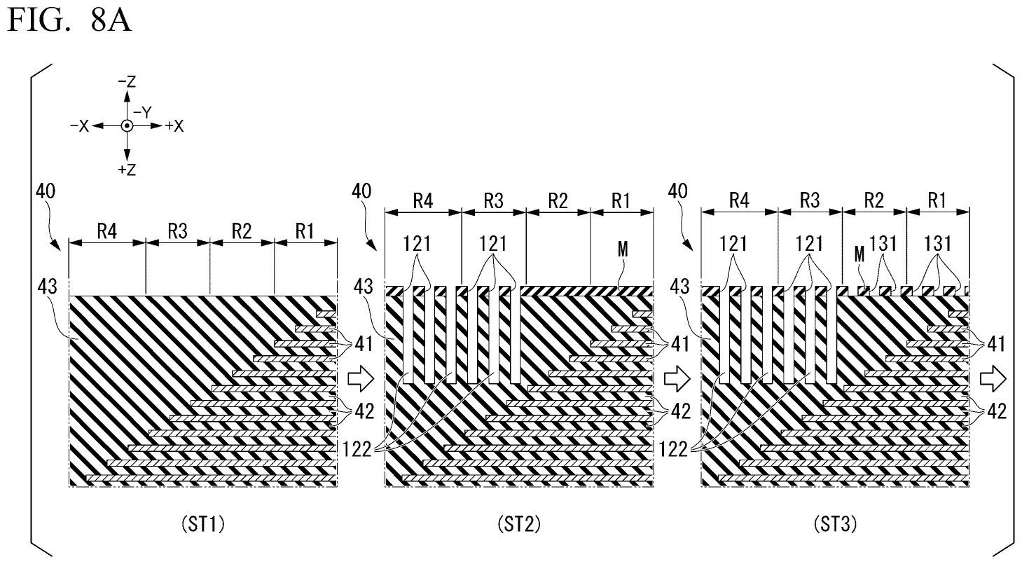

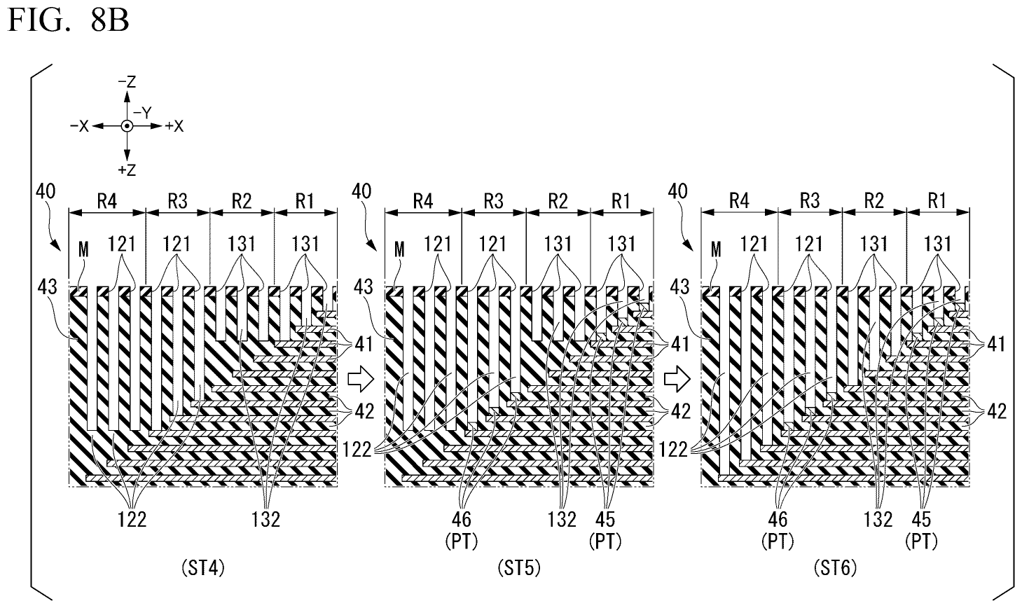

FIGS. 8A and 8B are views for explaining a manufacturing method of the semiconductor storage device 1. Further, in the following description, a formation method related to the staircase region SR will be described. Other portions of the semiconductor storage device 1 can be formed by known methods. Further, in FIGS. 8A and 8B, the insulating layer 42 and the insulating part 43 are shown integrally for convenience of explanation.

First, the multi-layered body 40 including the plurality of conductive layers 41, the plurality of insulating layers 42, and the insulating part 43 is formed (see (ST1) in FIG. 8A). The plurality of conductive layers 41 and the plurality of insulating layers 42 are alternately stacked one by one in the Z direction. The conductive layer 41 is an example of a “first layer”. The insulating layer 42 is an example of a “second layer”. The multi-layered body 40 has the first region R1, the second region R2, the third region R3, and the fourth region R4. These regions are aligned in the X direction in order of the first region R1, the second region R2, the third region R3, and the fourth region R4.

Formation of the multi-layered body 40 is performed, for example, by forming an intermediate multi-layered body in which a sacrificial layer and the insulating layer 42 are alternately stacked one by one in the Z direction, and then replacing the sacrificial layer with the conductive layer 41. Replacing the sacrificial layer with the conductive layer 41 is performed such that, for example, the sacrificial layer is removed from the intermediate multi-layered body by wet etching, and materials for forming the insulating film 103, the barrier metal film 102, and the conductive portion 101 are supplied in order to a space from which the sacrificial layer has been removed, and thereby the conductive layer 41 is formed.

Next, a mask M is formed to cover the multi-layered body 40. Then, a plurality of openings 121 for performing hole processing are formed in regions of the mask M corresponding to the third region R3 and the fourth region R4 of the multi-layered body 40 by, for example, lithography. Then, the hole processing is performed in the third region R3 and the fourth region R4 of the multi-layered body 40 through the plurality of openings 121 of the mask M. Therefore, a plurality of holes 122 each extending to a middle of the multi-layered body 40 in the Z direction are formed (see (ST2) in FIG. 8A).

Next, a plurality of openings 131 for performing the hole processing are formed in regions of the mask M corresponding to the first region R1 and the second region R2 of the multi-layered body 40 by, for example, lithography (see (ST3) in FIG. 8A).

Next, the hole processing is performed in the first region R1 and the second region R2 of the multi-layered body 40 through the plurality of openings 131 of the mask M, and the hole processing is resumed in the third region R3 and the fourth region R4 of the multi-layered body 40 using the plurality of openings 121 of the mask M. Then, the hole processing in the first region R1, the second region R2, the third region R3, and the fourth region R4 is stopped in a state in which the plurality of holes 132 formed in the second region R2 and the plurality of holes 122 formed in the fourth region R4 of the multi-layered body 40 do not reach the conductive layers 41 intended for connection respectively among the plurality of conductive layers 41, and the plurality of holes 132 formed in the first region R1 and the plurality of holes 122 formed in the third region R3 of the multi-layered body 40 reach the conductive layers 41 intended for connection respectively among the plurality of conductive layers 41 (see (ST4) in FIG. 8B).

Next, the conductive material of the conductive part 41 is supplied into each of the plurality of holes 131 formed in the first region R1 and the plurality of holes 121 formed in the third region R3 of the multi-layered body 40 by, for example, CVD to form the protruding part PT, which is a redeposition part, on the surface of the conductive part 41 (see (ST5) in FIG. 8B). The protruding part PT is a conductive part forming, for example, the first protruding part 45 or the second protruding part 46.

Next, hole processing in the first region R1, the second region R2, the third region R3, and the fourth region R4 of the multi-layered body 40 is resumed through the plurality of openings 121 and 131 of the mask M. At this time, the plurality of first protruding parts 45 are present in the first region R1, and the plurality of second protruding parts 46 are present in the third region R3 of the multi-layered body 40. Therefore, the plurality of first protruding parts 45 and the plurality of second protruding parts 46 function as stopper layers. In the first region R1 and the third region R3, the plurality of holes 122 and 132 penetrating the conductive layers 41 intended for connection and formed deeply therein is suppressed.

Then, the hole processing in the first region R1, the second region R2, the third region R3, and the fourth region R4 is stopped in a state in which the plurality of holes 132 formed in the second region R2 and the plurality of holes 122 formed in the fourth region R4 of the multi-layered body 40 reach the conductive layers 41 intended for connection respectively among the plurality of conductive layers 41 (see (ST6) in FIG. 8B). Thereafter, materials for the barrier metal film 112 and the conductive portion 111 are supplied in order into the plurality of holes 122 and 132. Therefore, the contacts 70 are formed. Therefore, formation of the staircase region SR is completed.

### 7. Advantages

As a comparative example, a configuration in which, in hole processing for providing the contact 70, a redeposition part of tungsten or the like is formed inside a plurality of holes corresponding to the conductive layers 41 on an upper half (a portion on the −Z direction side) of the plurality of conductive layers 41, thereby suppressing penetration of the hole through the conductive layers 41 on the upper half of the plurality of conductive layers 41 is conceivable. However, in this case, the hole processing in an upper layer portion (a portion on the −Z direction side) even in the upper half of the plurality of conductive layers 41 is difficult, and there is a likelihood that the hole will penetrate through the upper layer portion. Therefore, in the configuration of the comparative example described above, it is necessary to increase a film thickness of the redeposition part in the upper layer portion by, for example, providing redeposition steps a plurality of times. In this case, manufacturability of the semiconductor storage device decreases.

On the other hand, in the present embodiment, the semiconductor storage device 1 includes the multi-layered body 40 and the plurality of contacts 70. The multi-layered body 40 includes the plurality of conductive layers 41 and the plurality of insulating layers 42. The plurality of conductive layers 41 and the plurality of insulating layers 42 are alternately stacked one by one in the Z direction. The plurality of contacts 70 each extend in the Z direction. The multi-layered body 40 includes the first region R1, the second region R2, and the third region R3. The first region R1, the second region R2, and the third region R3 are aligned in the X direction in order of the first region R1, the second region R2, and the third region R3. The plurality of contacts 70 include the first contact 70A disposed in the first region R1, the second contact 70B disposed in the second region R2, and the third contact 70C disposed in the third region R3. The plurality of conductive layers 41 include the first conductive layer 41A, the second conductive layer 41B disposed on the +Z direction side with respect to the first conductive layer 41A, and the third conductive layer 41C disposed on the +Z direction side with respect to the second conductive layer 41B. The multi-layered body 40 includes the first conductive protruding part 45 that protrudes from the first conductive layer 41A toward the first contact 70A, and the second conductive protruding part 46 that protrudes from the third conductive layer 41C toward the third contact 70C. The first contact 70A is in contact with the first protruding part 45. The second contact 70B is in contact with the second conductive layer 41B. The third contact 70C is in contact with the second protruding part 46.

According to such a configuration, hole processing for providing the contact 70 can be performed separately into a region including the first region R1 and the second region R2 and a region including the third region R3. Therefore, even if the first protruding part 45 and the second protruding part 46 do not have a large thickness, penetration of the hole through the conductive layer 41 can be suppressed. Therefore, it is easier to form the first protruding part 45 and the second protruding part 46, and improvement in manufacturability of the semiconductor storage device 1 can be achieved.

### 8. Modified Example

Next, a modified example of the first embodiment will be described.

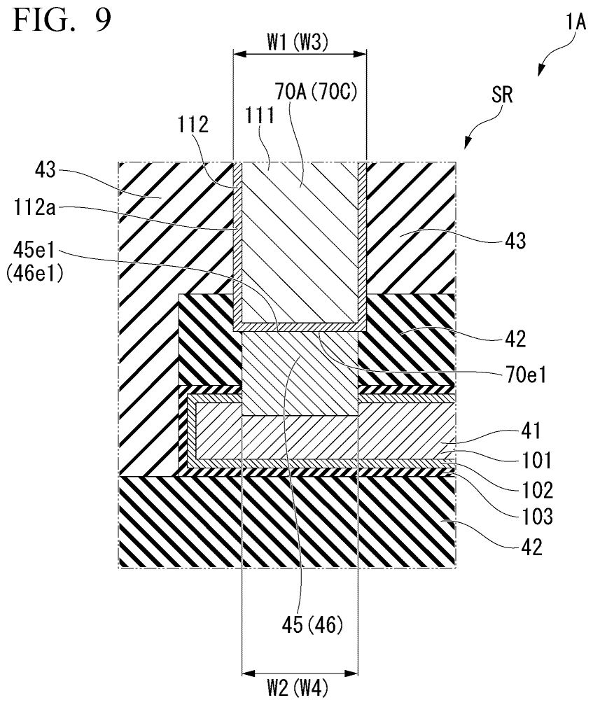

FIG. 9 is a cross-sectional view showing a staircase region SR of a semiconductor storage device 1A of a modified example of the first embodiment. In the present modified example, the contact 70A has an end 70e1 in contact with the first protruding part 45. The end 70e1 is an example of a “first end”. On the other hand, the first protruding part 45 has an end 45e1 in contact with the contact 70A. The end 45e1 is an example of a “second end”. Here, after the first protruding part 45 is provided, a diameter of the hole 132 (see FIG. 8B) for providing the contact 70A may be increased by wet etching, for example, for manufacturing reasons. In this case, a width W1 of the end 70e1 of the contact 70A in the X direction is larger than a width W2 of the end 45e1 of the first protruding part 45 in the X direction.

Similarly, the contact 70C has the end 70e1 in contact with the second protruding part 46. On the other hand, the second protruding part 46 has an end 46e1 in contact with the contact 70C. After the second protruding part 46 is provided, a diameter of the hole 122 (see FIG. 8B) for providing the contact 70C may be increased by wet etching, for example, for manufacturing reasons. In this case, a width W3 of the end 70e1 of the contact 70C in the X direction is larger than a width W4 of the end 46e1 of the second protruding part 46 in the X direction.

As described above, even if the contact 70 does not have the barrier metal film 112, if the width W1 of the end 70e1 of the contact 70A in the X direction is larger than the width W2 of the end 45e1 of the first protruding part 45 in the X direction, it can be said that the first protruding part 45 is present between the contact 70A and the conductive layer 41A. Similarly, if the width W3 of the end 70e1 of the contact 70C in the X direction is larger than the width W4 of the end 46e1 of the second protruding part 46 in the X direction, it can be said that the second protruding part 46 is present between the contact 70C and the conductive layer 41C.

### Second Embodiment

Next, a second embodiment will be described. The second embodiment differs from the first embodiment in that a staircase region SR is divided into six regions in the X direction. Further, configurations other than those described below are the same as the configurations in the first embodiment.

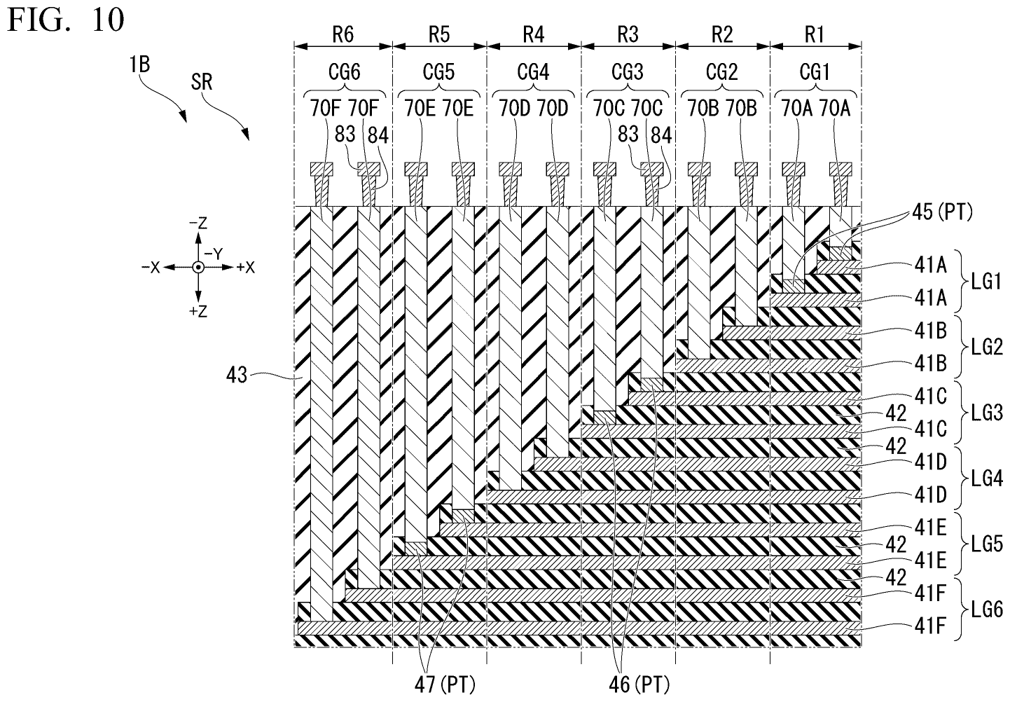

FIG. 10 is a cross-sectional view showing a semiconductor storage device 1B of the second embodiment. In the present embodiment, the staircase region SR has, for example, a first region R1, a second region R2, a third region R3, a fourth region R4, a fifth region R5, and a sixth region R6. These regions are aligned in the X direction in order of the first region R1, the second region R2, the third region R3, the fourth region R4, the fifth region R5, and the sixth region R6. The first region R1, the second region R2, the third region R3, the fourth region R4, the fifth region R5, and the sixth region R6 are, for example, regions in which the staircase region SR is divided into six in the X direction. However, sizes of the first region R1, the second region R2, the third region R3, the fourth region R4, the fifth region R5, and the sixth region R6 may be different from each other.

### (Contacts of First to Sixth Groups)

A plurality of contacts 70 are disposed separately in the first region R1, the second region R2, the third region R3, the fourth region R4, the fifth region R5, and the sixth region R6. The plurality of contacts 70 include a plurality of contacts 70A of a first group CG1, a plurality of contacts 70B of a second group CG2, a plurality of contacts 70C of a third group CG3, a plurality of contacts 70D of a fourth group CG4, a plurality of contacts 70E of a fifth group CG5, and a plurality of contacts 70F of a sixth group CG6.

The plurality of contacts 70E of the fifth group CG5 are the plurality of contacts 70 disposed in the fifth region R5. The plurality of contacts 70E of the fifth group CG5 extend further in the +Z direction as the contact 70E becomes positioned farther on the −X direction side in the fifth region R5. One contact 70E included in the plurality of contacts 70E of the fifth group CG5 is an example of a “fifth contact”.

The plurality of contacts 70F of the sixth group CG6 are the plurality of contacts 70 disposed in the sixth region R6. The plurality of contacts 70F of the sixth group CG6 extend further in the +Z direction as the contact 70F becomes positioned farther on the −X direction side in the sixth region R6. One contact 70F included in the plurality of contacts 70F of the sixth group CG6 is an example of a “sixth contact”.

### (Conductive Layers of First to Sixth Groups)

A plurality of conductive layers 41 include a plurality of conductive layers 41A of a first group LG1, a plurality of conductive layers 41B of a second group LG2, a plurality of conductive layers 41C of a third group LG3, a plurality of conductive layers 41D of a fourth group LG4, a plurality of conductive layers 41E of a fifth group LG5, and a plurality of conductive layers 41F of a sixth group LG6.

The plurality of conductive layers 41E of the fifth group LG5 are the plurality of conductive layers 41 corresponding to the plurality of contacts 70E of the fifth group CG5. The plurality of conductive layers 41E of the fifth group LG5 are disposed on the +Z direction side with respect to the plurality of conductive layers 41D of the fourth group LG4. The plurality of conductive layers 41E of the fifth group LG5 are disposed between the plurality of conductive layers 41D of the fourth group LG4 and the plurality of conductive layers 41F of the sixth group LG6 in the Z direction. One conductive layer 41E (one conductive layer 41E corresponding to the fifth contact described above) included in the plurality of conductive layers 41E of the fifth group LG5 is an example of a “fifth gate electrode layer”.

The plurality of conductive layers 41F of the sixth group LG6 are the plurality of conductive layers 41 corresponding to the plurality of contacts 70F of the sixth group CG6. The plurality of conductive layers 41F of the sixth group LG6 are disposed on the +Z direction side with respect to the plurality of conductive layers 41E of the fifth group LG5. One conductive layer 41F (one conductive layer 41F corresponding to the sixth contact described above) included in the plurality of conductive layers 41F of the sixth group LG6 is an example of a “sixth gate electrode layer”.

### (Conductive Protruding Part)

As shown in FIG. 10, a multi-layered body 40 includes a plurality of first protruding parts 45, a plurality of second protruding parts 46, and a plurality of third protruding parts 47.

The plurality of third protruding parts 47 are provided in the fifth region R5. The third protruding parts 47 are each provided on a surface on the −Z direction side of an end portion of the conductive layer 41E of the fifth group LG5. The third protruding part 47 is a conductive protruding part that protrudes in the −Z direction from the conductive layer 41E. The third protruding part 47 protrudes from the conductive layer 41E toward the contact 70E of the fifth group CG5. The third protruding part 47 is in contact with the contact 70E. In other words, the third protruding part 47 is disposed between the conductive layer 41E and the contact 70E in the Z direction. The third protruding part 47 electrically connects the conductive layer 41E and the contact 70E. Similar to the first protruding part 45 and the second protruding part 46, the third protruding part 47 is a redeposition part formed by re-depositing a material contained in the conductive layer 41.

In the present embodiment, the third protruding part 47 is provided on each of the plurality of conductive layers 41E of the fifth group LG5. Each contact 70E included in the plurality of contacts 70E of the fifth group CG5 is in contact with the third protruding part 47 provided on the conductive layer 41E that is included in the plurality of conductive layers 41E of the fifth group LG5 and corresponds to the contact 70E. In the following description, in a case in which the first protruding part 45, the second protruding part 46, and the third protruding part 47 do not need to be distinguished from each other, they will be referred to using a “protruding part PT”.

### (Manufacturing Method of Semiconductor Storage Device)

Next, a manufacturing method of the semiconductor storage device 1B of the second embodiment will be described.

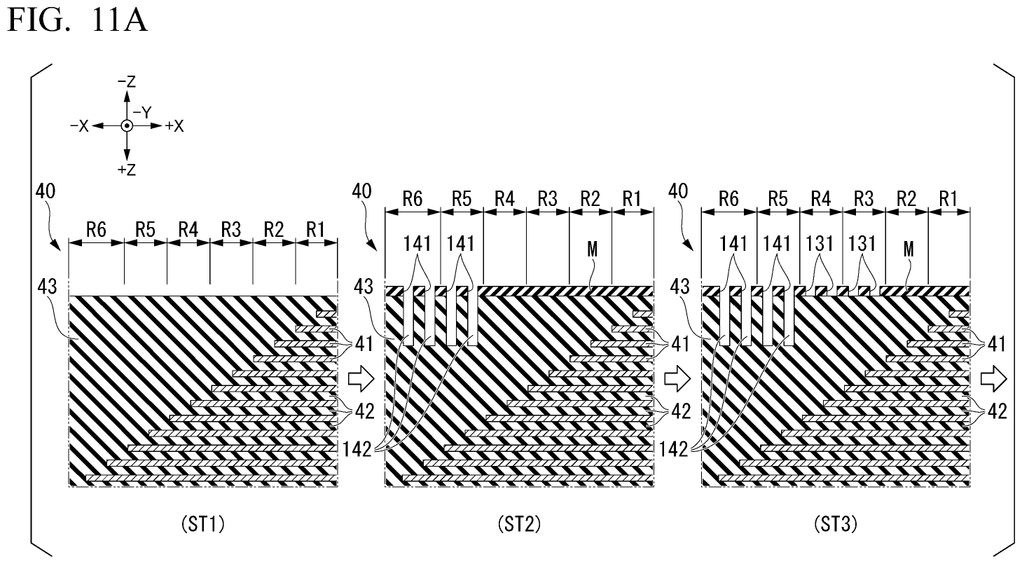

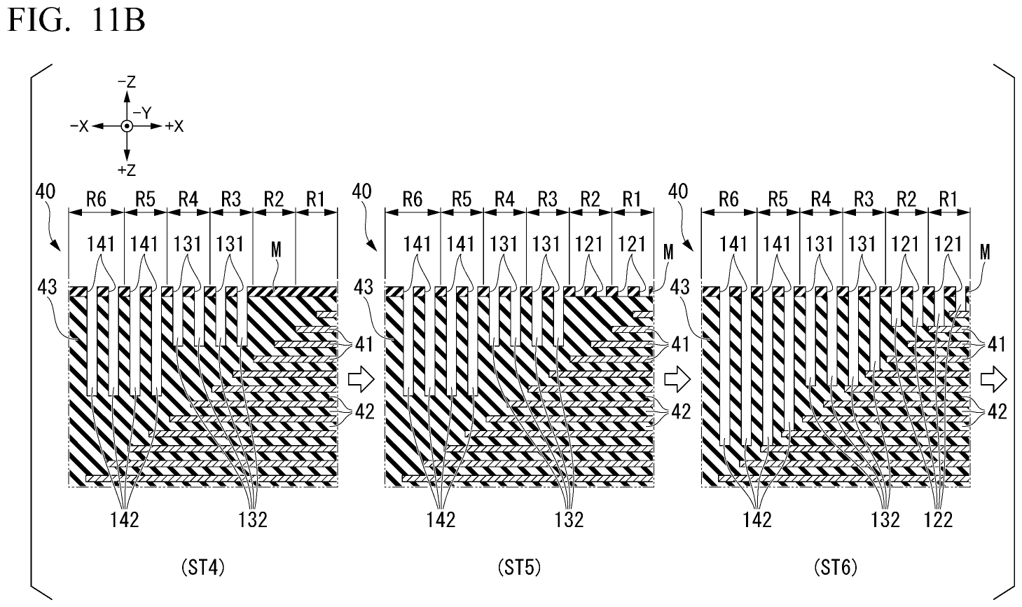

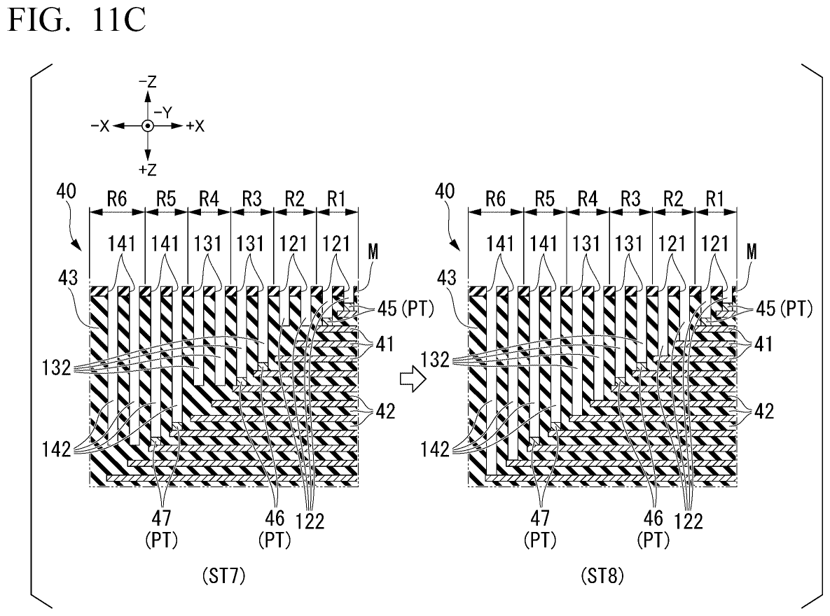

FIGS. 11A to 11C are views for explaining a manufacturing method of the semiconductor storage device 1B of the second embodiment. Further, in FIGS. 11A to 11C, an insulating layer 42 and an insulating part 43 are shown integrally for convenience of explanation.

First, the multi-layered body 40 is formed (see (ST1) in FIG. 11A) as in the first embodiment. Next, a mask M is formed to cover the multi-layered body 40. Then, a plurality of openings 141 for performing hole processing are formed in regions of the mask M corresponding to the fifth region R5 and the sixth region R6 of the multi-layered body 40 by, for example, lithography. Then, the hole processing is performed in the fifth region R5 and the sixth region R6 of the multi-layered body 40 through the plurality of openings 141 of the mask M. Therefore, a plurality of holes 142 each extending to a middle of the multi-layered body 40 in the Z direction are formed (see (ST2) in FIG. 11A).

Next, a plurality of openings 131 for performing the hole processing are formed in regions of the mask M corresponding to the third region R3 and the fourth region R4 of the multi-layered body 40 by, for example, lithography (see (ST3) in FIG. 11A).

Next, the hole processing is performed in the third region R3 and the fourth region R4 of the multi-layered body 40 through the plurality of openings 131 of the mask M, and the hole processing is resumed in the fifth region R5 and the sixth region R6 of the multi-layered body 40 using the plurality of openings 141 of the mask M. Then, the hole processing is performed in the third to sixth regions R3, R4, R5, and R6 of the multi-layered body 40 through the plurality of openings 131 and 141 of the mask M. Therefore, a plurality of holes 132 and 142 each extending to a middle of the multi-layered body 40 in the Z direction are formed (see (ST4) in FIG. 11B).

Next, a plurality of openings 121 for performing the hole processing are formed in regions of the mask M corresponding to the first region R1 and the second region R2 of the multi-layered body 40 by, for example, lithography (see (ST5) in FIG. 11B).

Next, the hole processing is performed in the first region R1 and the second region R2 of the multi-layered body 40 through the plurality of openings 121 of the mask M, and the hole processing is resumed in the third to sixth regions R3, R4, R5, and R6 of the multi-layered body 40 using the plurality of openings 131 and 141 of the mask M. Then, the hole processing in the first region R1, the second region R2, the third region R3, the fourth region R4, the fifth region R5, and the sixth region R6 is stopped in a state in which a plurality of holes 122 formed in the second region R2, the plurality of holes 132 formed in the fourth region R4, and the plurality of holes 142 formed in the sixth region R6 of the multi-layered body 40 do not reach the conductive layers 41 intended for connection respectively among the plurality of conductive layers 41, and the plurality of holes 122 formed in the first region R1, the plurality of holes 132 formed in the third region R3, and the plurality of holes 142 formed in the fifth region R5 of the multi-layered body 40 reach the conductive layers 41 intended for connection respectively among the plurality of conductive layers 41 (see (ST6) in FIG. 11B).

Next, a conductive material of the conductive part 41 is supplied into each of the plurality of holes 122 formed in the first region R1, the plurality of holes 132 formed in the third region R3, and the plurality of holes 142 formed in the fifth region R5 of the multi-layered body 40 by, for example, CVD to form the protruding part PT, which is a redeposition part, on a surface of the conductive part 41 (see (ST7) in FIG. 11B). The protruding part PT is a conductive part forming, for example, the first protruding part 45, the second protruding part 46, or the third protruding part 47.

Next, the hole processing in the first region R1, the second region R2, the third region R3, the fourth region R4, the fifth region R5, and the sixth region R6 of the multi-layered body 40 are resumed through the plurality of openings 121, 131, and 141 of the mask M. At this time, the plurality of first protruding parts 45 are present in the first region R1 of the multi-layered body 40, the plurality of second protruding parts 46 are present in the third region R3, and the plurality of third protruding parts 47 are present in the fifth region R5. Therefore, the plurality of first protruding parts 45, the plurality of second protruding parts 46, and the third protruding parts 47 function as stopper layers, and the plurality of holes 122, 132, and 142 penetrating the conductive layer 41 intended for connection and formed deeply therein in the first region R1, the third region R3, and the fifth region R5 is suppressed.

Then, the hole processing in the first region R1, the second region R2, the third region R3, the fourth region R4, the fifth region R5, and the sixth region R6 is stopped in a state in which the plurality of holes 122 formed in the second region R2, the plurality of holes 132 formed in the fourth region R4, and the plurality of holes 142 formed in the sixth region R6 of the multi-layered body 40 reach the conductive layers 41 intended for connection respectively among the plurality of conductive layers 41 (see (ST8) in FIG. 11C). Thereafter, materials for a barrier metal film 112 and a conductive portion 111 are supplied in order into the plurality of holes 122, 132, and 142. Therefore, the contacts 70 are formed. Therefore, formation of the staircase region SR is completed.

According to such a configuration, improvement in reliability of the semiconductor storage device 1B is achieved as in the first embodiment. Also, according to the present embodiment, since the number of divisions is larger than that in the first embodiment, even if the first protruding part 45, the second protruding part 46, and the third protruding part 47 are thin, penetration of the hole through the conductive layer 41 can be suppressed. Therefore, it is easier to form the protruding parts 45, 46, and 47, and improvement in manufacturability of the semiconductor storage device 1B can be achieved.

### Third Embodiment

Next, a third embodiment will be described. The third embodiment differs from the first embodiment in that the configuration of the first embodiment is applied to a multi-row staircase type staircase region SR. Further, configurations other than those described below are the same as the configurations in the first embodiment.

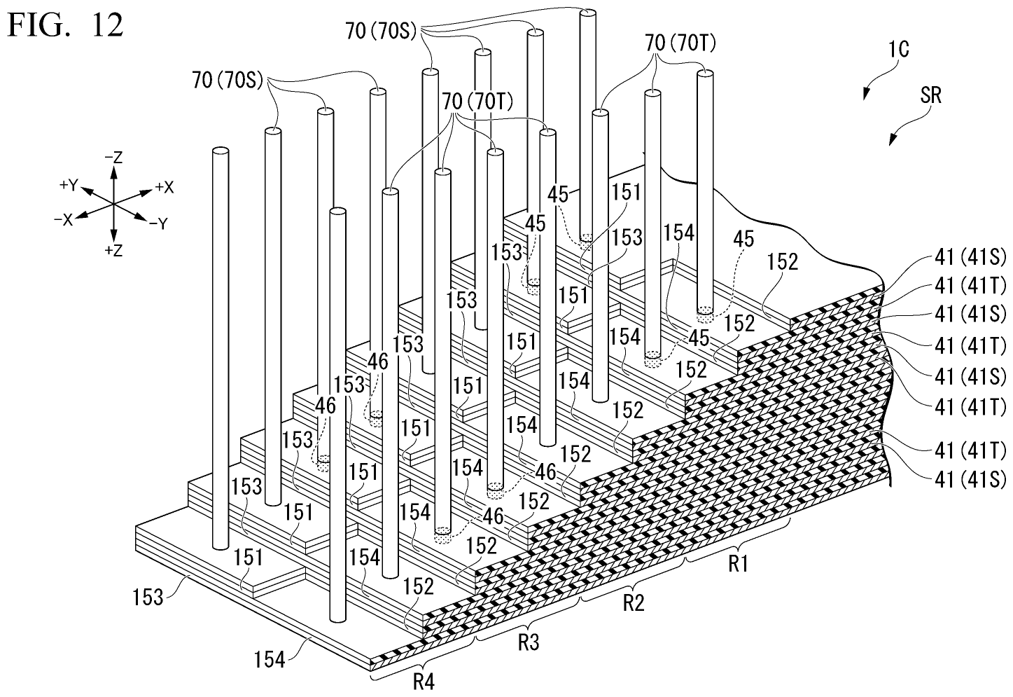

FIG. 12 is a perspective cross-sectional view showing a staircase region SR of a semiconductor storage device 1C of the third embodiment. In the present embodiment, a plurality of conductive layers 41 have a multi-row staircase type staircase region SR. For example, FIG. 12 shows a two-row staircase type staircase region SR as an example of the multi-row staircase type. Further, FIG. 12 schematically shows four conductive layers 41 in each of regions R1, R2, R3, and R4.

In the third embodiment, the odd-numbered conductive layer 41 in the Z direction (hereinafter referred to as a “conductive layer 41S” for convenience of explanation) has a first portion 151 and a second portion 152. The first portion 151 and the second portion 152 are aligned in the Y direction in each conductive layer 41S. A length of the second portion 152 in the − direction is smaller than a length of the first portion 151 in the −X direction.

On the other hand, the conductive layer 41 adjacent to the conductive layer 41S from a +Z direction (hereinafter referred to as a “conductive layer 41T” for convenience of explanation) has a third portion 153 and a fourth portion 154. The third portion 153 and the fourth portion 154 are aligned in the Y direction in each conductive layer 41T. The third portion 153 is positioned on the +Z direction side of the first portion 151 of the conductive layer 41S. The fourth portion 154 is positioned on the +Z direction side of the second portion 152 of the conductive layer 41S. A length of each of the third portion 153 and the fourth portion 154 in the −X direction is the same as a length of the first portion 151 of the conductive layer 41S in the −X direction. As a result, the third portion 153 of the conductive layer 41T is covered with the first portion 151 of the conductive layer 41S. On the other hand, the fourth portion 154 of the conductive layer 41T is exposed in the −Z direction without being covered with the second portion 152 of the conductive layer 41S.

In the present embodiment, a plurality of contacts 70 include a contact 70S electrically connected to the first portion 151 of the conductive layer 41S and a contact 70T electrically connected to the fourth portion 154 of the conductive layer 41T. The contact 70S and the contact 70T are aligned in the Y direction. According to such a configuration, a length of the staircase region SR in the −X direction can be made small.

Then, in the present embodiment, a first protruding part 45 is provided between each contact 70S disposed in the first region R1 of a multi-layered body 40 and the first portion 151 of the conductive layer 41S corresponding to the contact 70S. Also, the first protruding part 45 is provided between each contact 70T disposed in the first region R1 of the multi-layered body 40 and the fourth portion 154 of the conductive layer 41T corresponding to the contact 70T.

Similarly, a second protruding part 46 is provided between each contact 70S disposed in the third region R3 of the multi-layered body 40 and the first portion 151 of the conductive layer 41S corresponding to the contact 70S. Also, the second protruding part 46 is provided between each contact 70T disposed in the third region R3 of the multi-layered body 40 and the fourth portion 154 of the conductive layer 41T corresponding to the contact 70T.

On the other hand, in the second region R2 and the fourth region R4 of the multi-layered body 40, there is no protruding part PT between each contact 70S and the first portion 151 of the conductive layer 41S corresponding to the contact 70S, and each contact 70S is in contact with the first portion 151 of the conductive layer 41S. Similarly, in the second region R2 and the fourth region R4 of the multi-layered body 40, there is no protruding part PT between each contact 70T and the fourth portion 154 of the conductive layer 41T corresponding to the contact 70T, and each contact 70T is in contact with the fourth portion 154 of the conductive layer 41T.

According to such a configuration, improvement in manufacturability of the semiconductor storage device 1C can be achieved as in the first embodiment. Further, in the present embodiment, the staircase region SR of a two-row staircase type has been described. However, the embodiment is not limited to the above-described example. For example, the semiconductor storage device 1C may have a multi-row staircase type staircase region SR having three or more rows.

### Modified Example

Next, modified examples regarding the first to third embodiments will be described.

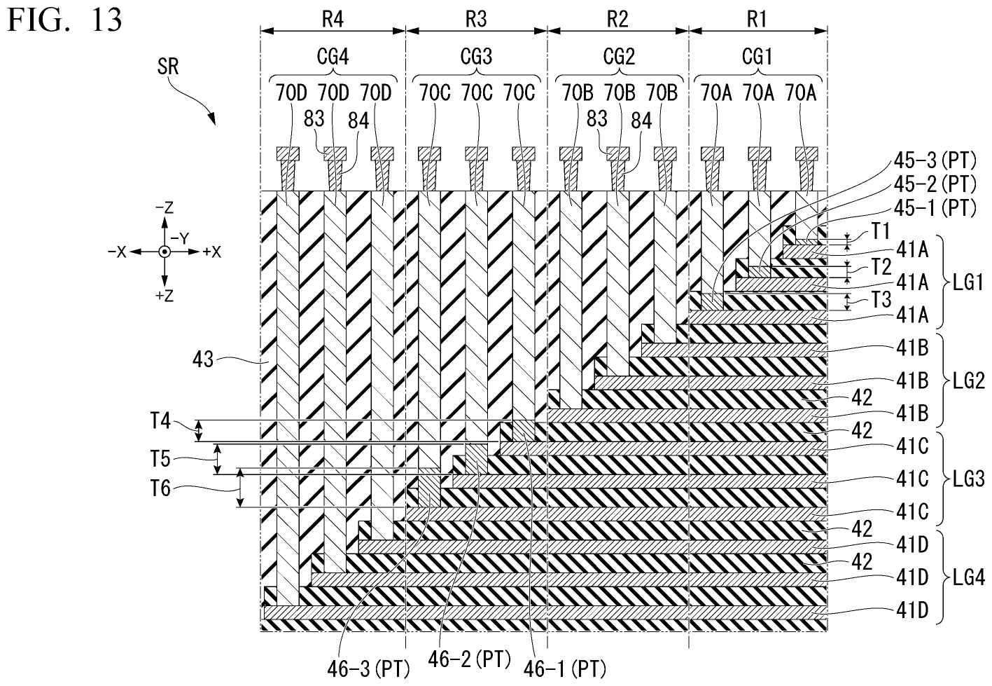

FIG. 13 is a cross-sectional view showing a staircase region SR of a semiconductor storage device 1D according to a modified example of the embodiments. FIG. 13 is a modified example corresponding to, for example, the configuration of the semiconductor storage device 1 of the first embodiment. In the present modified example, a thickness of the protruding part PT in the Z direction increases as the protruding part PT becomes positioned farther on the +Z direction side.

For example, a plurality of protruding parts 45 provided in the first region R1 include a protruding part 45-1, a protruding part 45-2, and a protruding part 45-3.

The protruding part 45-2 is disposed on the +Z direction side compared to the protruding part 45-1. In other words, the conductive layer 41A provided with the protruding part 45-2 is positioned on the +Z direction side with respect to the conductive layer 41A provided with the protruding part 45-1. In the present modified example, a thickness T2 of the protruding part 45-2 in the Z direction is larger than a thickness T1 of the protruding part 45-1 in the Z direction.

The protruding part 45-3 is disposed on the +Z direction side compared to the protruding part 45-2. In other words, the conductive layer 41A provided with the protruding part 45-3 is positioned on the +Z direction side with respect to the conductive layer 41A provided with the protruding part 45-2. In the present modified example, a thickness T3 of the protruding part 45-3 in the Z direction is larger than the thickness T2 of the protruding part 45-2 in the Z direction.

Similarly, the plurality of protruding parts 46 provided in the third region R3 include a protruding part 46-1, a protruding part 46-2, and a protruding part 46-3.

The protruding part 46-1 is disposed on the +Z direction side compared to the protruding part 45-3 provided in the first region R1. In other words, the conductive layer 41C provided with the protruding part 46-1 is positioned on the +Z direction side with respect to the conductive layer 41A provided with the protruding part 45-3. In the present modified example, a thickness T4 of the protruding part 46-1 in the Z direction is larger than the thickness T3 of the protruding part 45-3 in the Z direction.

The protruding part 46-2 is disposed on the +Z direction side compared to the protruding part 46-1. In other words, the conductive layer 41C provided with the protruding part 46-2 is positioned on the +Z direction side with respect to the conductive layer 41C provided with the protruding part 46-1. In the present modified example, a thickness T5 of the protruding part 46-2 in the Z direction is larger than the thickness T4 of the protruding part 46-1 in the Z direction.

The protruding part 46-3 is disposed on the +Z direction side compared to the protruding part 46-2. In other words, the conductive layer 41C provided with the protruding part 46-3 is positioned on the +Z direction side with respect to the conductive layer 41C provided with the protruding part 46-2. In the present modified example, a thickness T6 of the protruding part 46-3 in the Z direction is larger than the thickness T5 of the protruding part 46-2 in the Z direction.

The above-described configuration is realized, for example, when the protruding part PT positioned farther on the −Z direction side is further cut away by etching during processing of the hole 122 or the hole 132. However, the configuration described above may be realized for a reason different from the etching described above.

Further, the configuration of the present modified example may be applied to the configuration of the second embodiment. In this case, regarding the plurality of protruding parts PT included in the first region R1, the third region R3, and the fifth region R5, a thickness of the protruding part PT in the Z direction increases as the protruding part PT becomes positioned farther on the +Z direction side.

Preferred embodiments and modified examples have been described above. However, the embodiments and modified examples are not limited to the examples described above. For example, the protruding part PT may not be present on some of the conductive layers 41 positioned on the −Z direction side among the plurality of conductive layers 41 (for example, some conductive layers 41 on the −Z direction side among the plurality of conductive layers 41 to which the contact 70A is electrically connected in the first region R1). For example, some of the conductive layers 41 positioned on the −Z direction side among the plurality of conductive layers 41 (for example, some conductive layers 41 on the −Z direction side among the plurality of conductive layers 41 to which the contact 70A is electrically connected in the first region R1) may have the protruding parts PT disappeared by being cut away by etching during processing of the hole 122, the hole 132, or the like. Also, some of the conductive layers 41 positioned on the −Z direction side among the plurality of conductive layers 41 (for example, some conductive layers 41 on the −Z direction side among the plurality of conductive layers 41 to which the contact 70A is electrically connected in the first region R1) may be over-etched to such an extent that they are not penetrated during processing of the hole 122, the hole 132, or the like, and an end portion of the contact 70 on the +Z direction side may enter the inside of the conductive layer 41.

According to at least one embodiment described above, a semiconductor storage device includes a multi-layered body and a plurality of contacts. The multi-layered body includes a plurality of gate electrode layers and a plurality of insulating layers. The plurality of contacts include a first contact, a second contact, and a third contact. The plurality of gate electrode layers include a first gate electrode layer, a second gate electrode layer disposed on a first side with respect to the first gate electrode layer, and a third gate electrode layer disposed on the first side with respect to the second gate electrode layer. The multi-layered body includes a first protruding part that has electroconductivity and protrudes from the first gate electrode layer toward the first contact, and a second protruding part that has electroconductivity and protrudes from the third gate electrode layer toward the third contact. The first contact is in contact with the first protruding part. The second contact is in contact with the second gate electrode layer. The third contact is in contact with the second protruding part. According to such a configuration, improvement in manufacturability of the semiconductor storage device can be achieved.

Preferred embodiments have been described above. However, the embodiments are not limited to the examples described above. For example, the staircase region SR may be divided into eight or more instead of four or six.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a multi-layered body including a plurality of gate electrode layers and a plurality of insulating layers, the plurality of gate electrode layers and the plurality of insulating layers are alternately stacked one by one in a first direction in the multi-layered body; and
a plurality of contacts each extending in the first direction, wherein
the multi-layered body includes a first region, a second region, and a third region,
the first region, the second region, and the third region are in a second direction different from the first direction in order of the first region, the second region, and the third region,
the plurality of contacts include a first contact in the first region, a second contact in the second region, and a third contact in the third region,
the plurality of gate electrode layers include a first gate electrode layer, a second gate electrode layer, and a third gate electrode layer,
the second gate electrode layer is on a first side in the first direction with respect to the first gate electrode layer,
the third gate electrode layer is on the first side with respect to the second gate electrode layer,
the multi-layered body includes a first protruding part and a second protruding part,
the first protruding part has electroconductivity,
the first protruding part protrudes from the first gate electrode layer toward the first contact,
the second protruding part has electroconductivity,
the second protruding part protrudes from the third gate electrode layer toward the third contact,
the first contact is in contact with the first protruding part,
the second contact is in contact with the second gate electrode layer, and
the third contact is in contact with the second protruding part.

2. The semiconductor storage device according to claim 1, wherein
when a side opposite to the first side in the first direction is defined as a second side,
the plurality of contacts include a plurality of contacts of a first group in the first region,
the first group includes the first contact,
the plurality of gate electrode layers include a plurality of gate electrode layers of a first group,
the first group is on the second side with respect to the second gate electrode layer,
the first group includes the first gate electrode layer,
the first protruding part is on each of the plurality of gate electrode layers of the first group,
each contact included in the plurality of contacts of the first group is in contact with the first protruding part,
the first protruding part is on a gate electrode layer included in the plurality of gate electrode layers of the first group and corresponding to the contact.

3. The semiconductor storage device according to claim 2, wherein
the plurality of contacts include a plurality of contacts of a second group in the second region,
the second group includes the second contact,
the plurality of gate electrode layers include a plurality of gate electrode layers of a second group,
the second group is between the plurality of gate electrode layers of the first group and the third gate electrode layer,
the second group includes the second gate electrode layer,
each contact included in the plurality of contacts of the second group is in contact with a gate electrode layer included in the plurality of gate electrode layers of the second group and corresponding to the contact.

4. The semiconductor storage device according to claim 3, wherein
the plurality of contacts include a plurality of contacts of a third group in the third region,
the third group includes the third contact,
the plurality of gate electrode layers include a plurality of gate electrode layers of a third group,
the third group is on the first side with respect to the gate electrode layer of the second group,
the third group includes the third gate electrode layer,
the second protruding part is on each gate electrode layer of the third group,
each contact included in the plurality of contacts of the third group is in contact with the second protruding part on a gate electrode layer included in the plurality of gate electrode layers of the third group and corresponding to the contact.

5. The semiconductor storage device according to claim 1, wherein
the second gate electrode layer has a length in the second direction larger than that of the first gate electrode layer in a connection region,
the plurality of contacts and the plurality of gate electrode layers are connected in the connection region, and
the third gate electrode layer has a length in the second direction larger than that of the second gate electrode layer in the connection region.

6. The semiconductor storage device according to claim 1, wherein
each of the first contact, the second contact, and the third contact includes a barrier metal film, and
in a cross section in the first direction and the second direction, a shortest distance between the barrier metal film of the second contact and the second gate electrode layer is smaller than a shortest distance between the barrier metal film of the first contact and the first gate electrode layer, and is smaller than a shortest distance between the barrier metal film of the third contact and the third gate electrode layer.

7. The semiconductor storage device according to claim 1, wherein
the first contact includes a first end in contact with the first protruding part,
the first protruding part includes a second end in contact with the first end of the first contact, and
a width of the first end in the second direction is larger than a width of the second end in the second direction.

8. The semiconductor storage device according to claim 1, wherein
each of the first gate electrode layer, the second gate electrode layer, and the third gate electrode layer contains a first material, the first material being tungsten, molybdenum, or silicon, and
each of the first protruding part and the second protruding part is a redeposition part of the first material.

9. The semiconductor storage device according to claim 1, wherein
the multi-layered body includes a fourth region and a fifth region,
the first region, the second region, the third region, the fourth region, and the fifth region are in the second direction in order of the first region, the second region, the third region, the fourth region, and the fifth region,
the plurality of contacts include a fourth contact in the fourth region and a fifth contact in the fifth region,
the plurality of gate electrode layers include a fourth gate electrode layer and a fifth gate electrode layer,
the fourth gate electrode layer is on the first side with respect to the third gate electrode layer,
the fifth gate electrode layer is on the first side with respect to the fourth gate electrode layer,
the multi-layered body includes a conductive third protruding part protruding from the fifth gate electrode layer toward the fifth contact,
the fourth contact is in contact with the fourth gate electrode layer, and
the fifth contact is in contact with the third protruding part.

10. A manufacturing method of a semiconductor storage device, comprising:
forming a multi-layered body, the multi-layered body including a plurality of first layers and a plurality of second layers, the plurality of first layers and the plurality of second layers are alternately stacked one by one in a first direction in the multi-layered body, the multi-layered body including a first region, a second region, and a third region, the first region, the second region, and the third region being in a second direction different from the first direction in order of the first region, the second region, and the third region, and the plurality of first regions containing a first material;
performing hole processing in the third region, thereby forming a plurality of holes each extending to a middle of the multi-layered body in the first direction;
performing the hole processing in the first region and the second region and resuming the hole processing in the third region, thereby stopping the hole processing in the first region, the second region, and the third region, in a state in which a plurality of holes formed in the second region do not reach layers intended for connection respectively among the plurality of first layers, and a plurality of holes formed in the first region and the plurality of holes formed in the third region reach layers intended for connection respectively among the plurality of first layers;
forming a redeposition part of the first material inside each of the plurality of holes formed in the first region and the plurality of holes formed in the third region; and
resuming the hole processing in the first region, the second region, and the third region.
